(19) United States
(12) Patent Application Publication
(10) Pub. No.: US 2025/0355058 A1
(43) Pub. Date: Nov. 20, 2025

(54) DETECTION CIRCUIT, SIGNAL TRANSMISSION DEVICE, ELECTRONIC DEVICE, AND VEHICLE

(71) Applicant: ROHM CO., LTD., Kyoto-shi (JP)

(72) Inventors: Daiki YANAGISHIMA, Kyoto-shi (JP); Chinatsu NAKAOKA, Kyoto-shi (JP)

(21) Appl. No.: 19/202,429

(22) Filed: May 8, 2025

(30) Foreign Application Priority Data
May 17, 2024 (JP) 2024-081165
Feb. 25, 2025 (JP) 2025-027703

(51) Int. Cl. G01R 31/52; G01R 31/00; G05F 1/56; H03K 5/24

(52) U.S. Cl. CPC G01R 31/52; G01R 31/006; G05F 1/56; H03K 5/24

(57) ABSTRACT

The detection circuit includes a first comparator configured to compare a node voltage, which corresponds to a drain-source voltage or a collector-emitter voltage of a power transistor, and a first reference voltage with each other to generate a first comparison signal, a second comparator configured to compare a gate voltage of the power transistor and a second reference voltage with each other to generate a second comparison signal, and a logic circuit configured to output a detection signal upon reception of inputs of the first comparison signal and the second comparison signal.

### CROSS REFERENCE TO RELATED APPLICATIONS

The present invention claims priority under 35 U.S.C. § 119 to Japanese Patent Applications No. 2024-081165 filed on May 17, 2024, and Japanese Patent Application No. 2025-027703 filed on Feb. 25, 2025, the contents of which are hereby incorporated by reference.

### BACKGROUND

### 1. Technical Field

The present disclosure relates to a detection circuit, a signal transmission device, an electronic device, and a vehicle.

### 2. Description of Related Art

Conventionally, signal transmission devices that transmit a signal between a primary circuit system and a secondary circuit system while keeping electrical isolation between the primary and secondary circuit systems are used in various applications (such as power supply devices or motor driving devices).

One example of the known technology mentioned above is seen in Patent Document 1 (International Application: WO 2022/070944) filed by the present applicant.

### BRIEF DESCRIPTION OF THE DRAWINGS

FIG. 1 is a diagram illustrating the basic configuration of a signal transmission device.

FIG. 2 is a diagram illustrating the basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view of a layer in the semiconductor device shown in FIG. 3 where low-potential coils are formed.

FIG. 6 is a plan view of a layer in the semiconductor device shown in FIG. 3 where high-potential coils are formed.

FIG. 7 is a cross-sectional view taken along line VIII-VIII shown in FIG. 6.

FIG. 8 is an enlarged view (showing a separation structure) of region XIII shown in FIG. 7.

FIG. 9 is a diagram schematically showing an example of the layout of a transformer chip.

FIG. 10 is a diagram showing a first embodiment (comparative example) of a detection circuit.

FIG. 11 is a chart showing a detection operation for a load short circuit in the first embodiment.

FIG. 12 is a diagram showing a second embodiment of the detection circuit.

FIG. 13 is a chart showing a detection operation for a load short circuit in the second embodiment.

FIG. 14 is a diagram showing a third embodiment of the detection circuit.

FIG. 15 is a diagram showing a fourth embodiment of the detection circuit.

FIG. 16 is a chart showing a relationship between a slew rate of a gate-source voltage and individual-component voltages in the second embodiment.

FIG. 17 is a chart showing a misdetection of a load short circuit in the second embodiment.

FIG. 18 is a chart showing a first setting example of blanking time.

FIG. 19 is a diagram showing a fifth embodiment of the detection circuit.

FIG. 20 is a chart showing a detection operation for a load short circuit in the fifth embodiment.

FIG. 21 is a chart showing a second setting example of the blanking time.

FIG. 22 is a diagram showing a sixth embodiment of the detection circuit.

FIG. 23 is a chart showing a detection operation for a load short circuit in the sixth embodiment.

FIG. 24 is a chart showing a third setting example of the blanking time.

FIG. 25 is a diagram showing a seventh embodiment of the detection circuit.

FIG. 26 is a chart showing a detection operation for a load short circuit in the seventh embodiment.

FIG. 27 is a diagram showing an eighth embodiment of the detection circuit.

FIG. 28 is a chart showing a detection operation for a load short circuit in the eighth embodiment.

FIG. 29 is a view showing an appearance of a vehicle.

### DETAILED DESCRIPTION

### Signal Transmission Device (Basic Configuration)

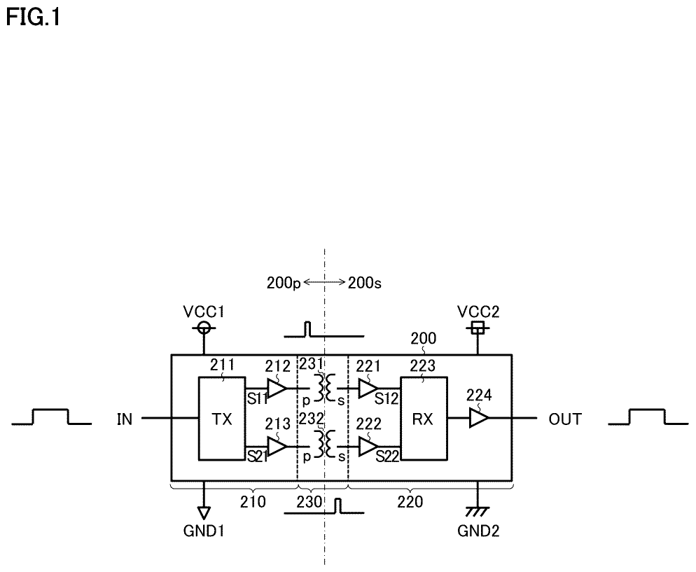

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drives the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and $21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low-to middle-withstand-voltage process (with a withstand voltage of several volts to several tens of volts). This eliminates the need for a dedicated high-withstand-voltage process (with a withstand voltage of several kilovolts) and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### Transformer Chip (Basic Structure)

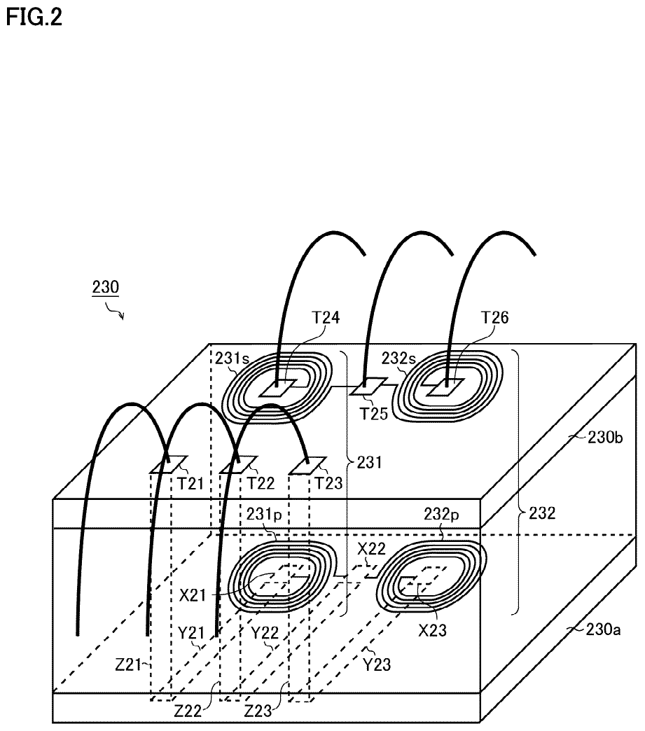

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 232s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230 and is DC-isolated from the controller chip 210 by the transformer chip 230.

### Transformer Chip (Two-Channel Type)

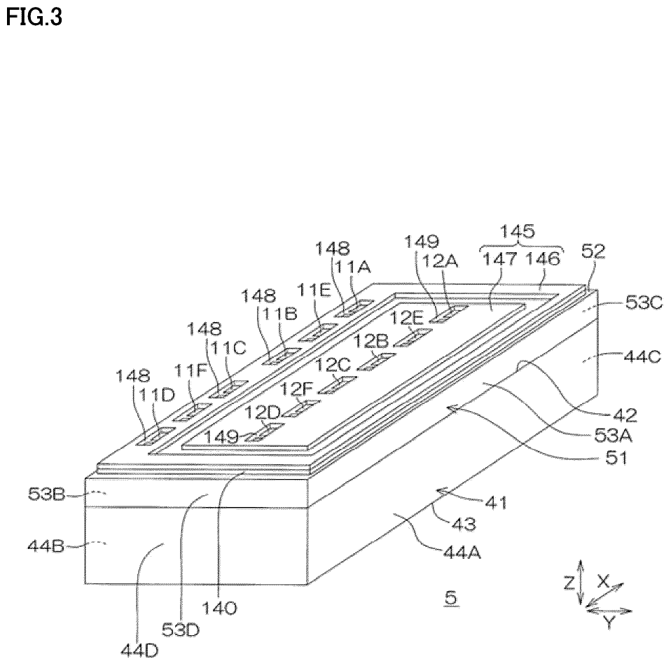

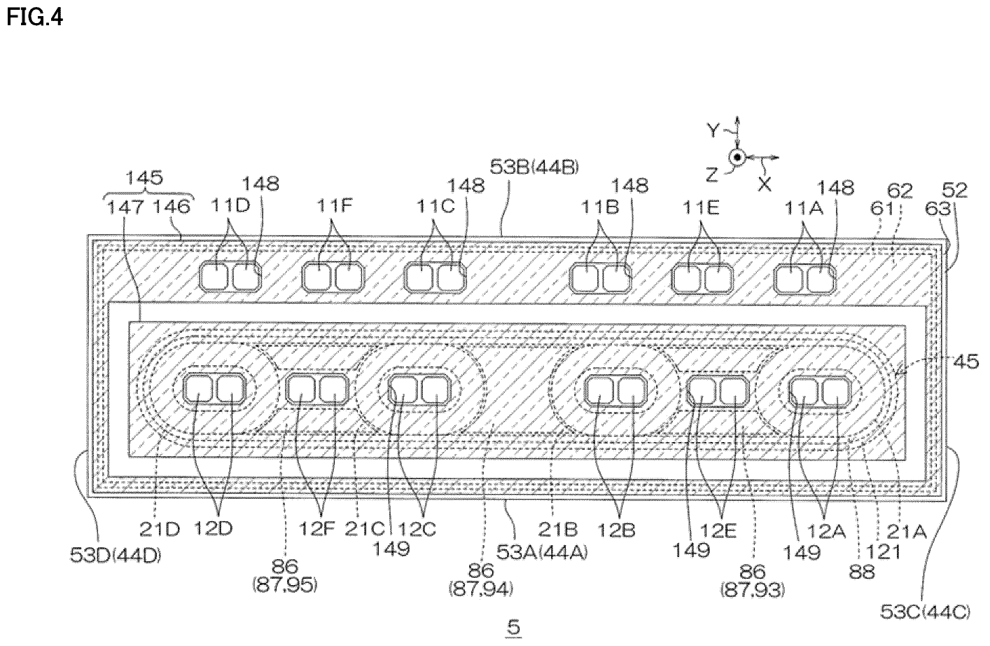

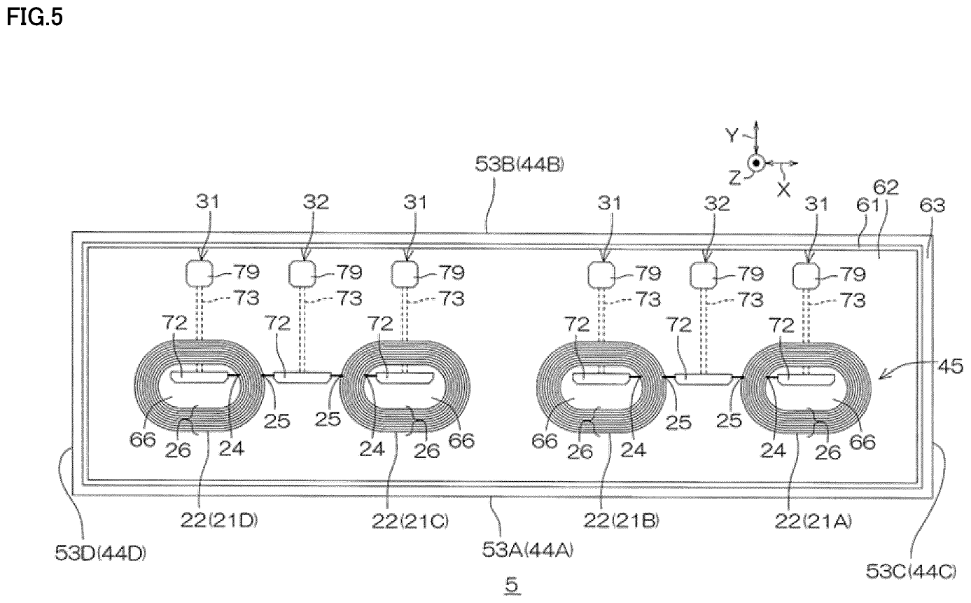

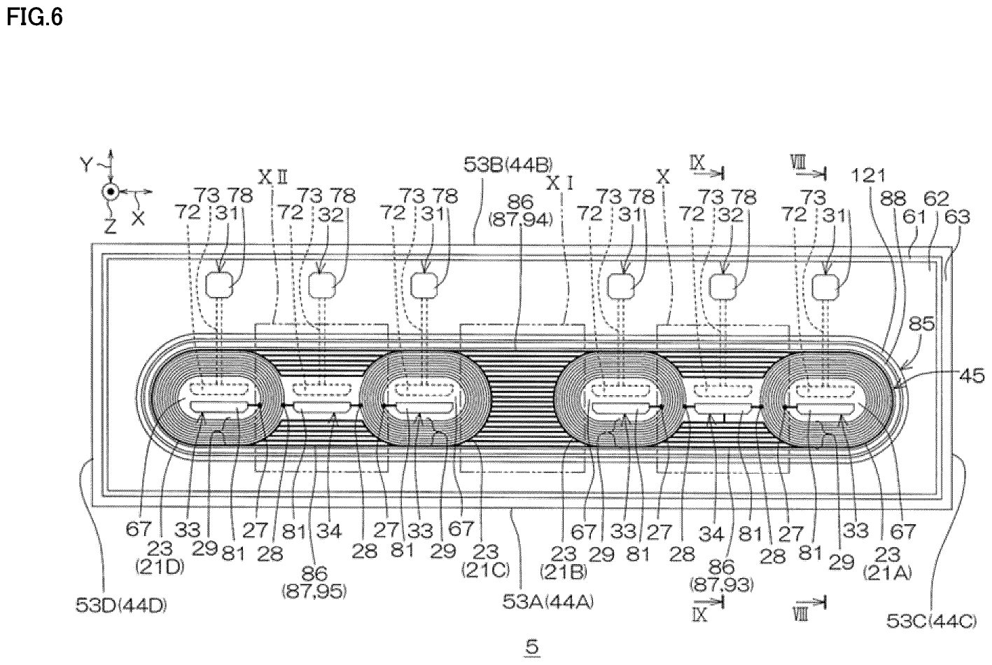

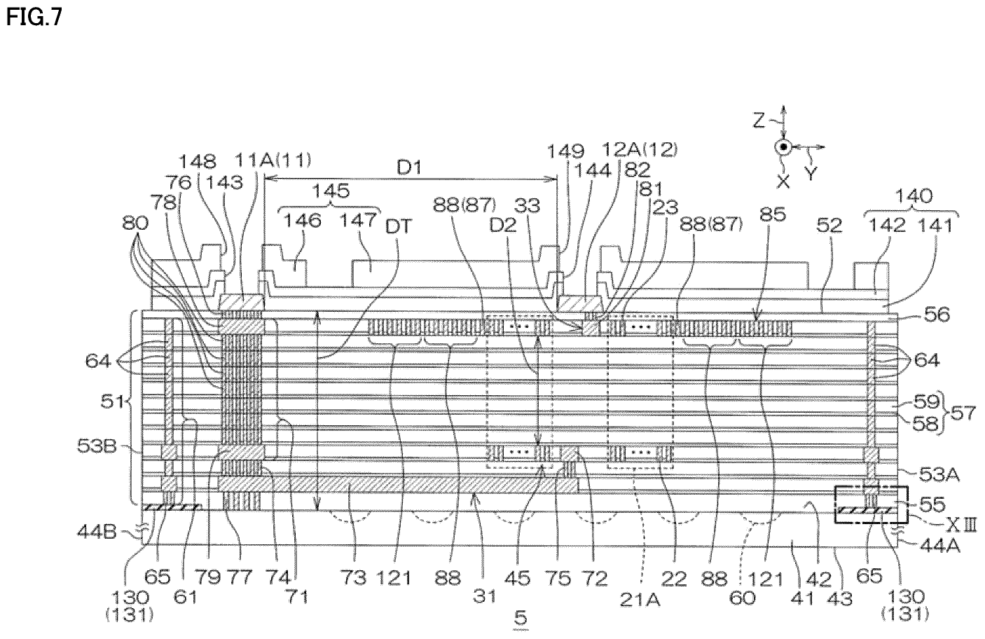

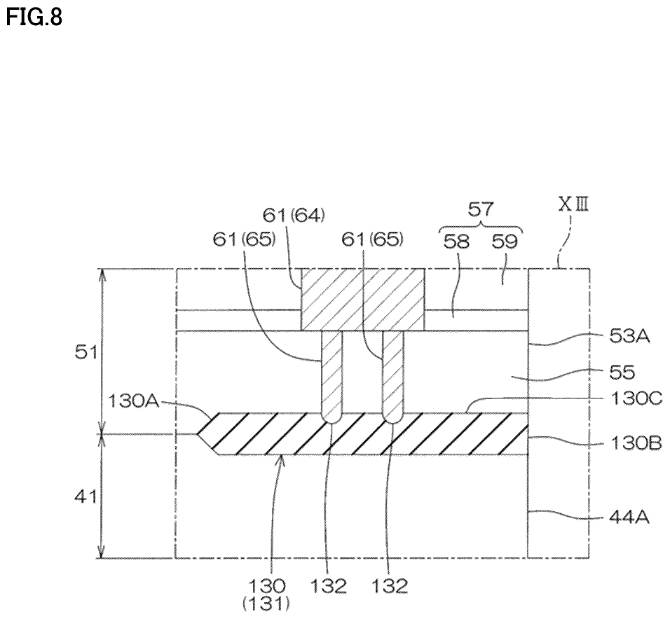

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6. FIG. 8 is an enlarged view of region XIII shown in FIG. 7, which shows a separation structure 130.

Referring to FIGS. 3 to FIG. 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AIN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D includes a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41 and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58, and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding to the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIGS. 5 to FIG. 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low-and high-potential coils 22 and 23 are formed in a region between the bottom and top insulation layers 55 and 56 (i.e., in the plurality of interlayer insulation layers 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low-and high-potential coils 22 and 23 can be disposed at any places. The high-potential coil 23 can face the low-potential coil 22 across one or more interlayer insulation layers 57.

The distance between the low-and high-potential coils 22 and 23 (i.e., the number of interlayer insulation layers 57 stacked together) is adjusted appropriately according to the dielectric strength voltage and electric field strength between the low-and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIG. 5 and FIG. 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23 and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layers 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41 and extends in the shape of a stripe in a region between the first and second end parts.

The first connection plug electrode 74 is formed in the interlayer insulation layer 57, in a region between the through wiring 71 and the lead wiring 73 and is electrically connected to the through wiring 71 and to the first end part of the lead wiring 73. The second connection plug electrode 75 is formed in the interlayer insulation layer 57, in a region between the low-potential connection wiring 72 and the lead wiring 73 and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71 and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73 and are electrically connected to the semiconductor chip 41 and to the first end part of the lead wiring 73.

Referring to FIG. 6 and FIG. 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low-and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81 and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low-and high-potential terminals 11 and 12 is larger than the distance D2 between the low-and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any values, which are adjusted appropriately according to the desired dielectric strength voltage.

Referring to FIG. 6 and FIG. 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high-and low-potential coils 23 and 22, and is independent of the transformers 21A to 21D. That is, the dummy pattern 85 does not function as part of the transformers 21A to 21D. The dummy pattern 85 is formed as a shield conductor layer that shields electric fields between the low-and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41, and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low-and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIGS. 5 to FIG. 7, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D as seen in a plan view. In the embodiment, the sealing conductor 61 is formed in a quadrangular ring shape (specifically, a rectangular ring shape) as seen in a plan view. Thus, the sealing conductor 61 defines the device region 62 in a quadrangular shape (specifically, a rectangular shape) as seen in a plan view. Furthermore, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41 and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively and are each formed in a quadrangular ring shape (specifically, a rectangular ring shape) surrounding the device region 62. The plurality of sealing plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductors 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41, and are connected to the sealing plug conductors 64. The plurality of sealing via conductors 65 have a plane area smaller than the plane area of the sealing plug conductors 64. In a case where a single sealing via conductor 65 is formed, the single sealing via conductors 65 can have a plane area equal to or larger than the plane area of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIG. 7 and FIG. 8, the semiconductor device 5 further includes the separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41 and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41, and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61, and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low-and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlap parts that overlap circumferential edges (overlap parts) of the low-potential pad openings 143.

The second part 147 is formed at an interval from the first part 146, and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low-and high-potential terminals 11 and 12, it is possible suppress unnecessary conduction between the high-potential terminal 12 and the sealing conductor 61. Likewise, in a case where a voltage is applied to the second functional device 60 via the low-and high-potential terminals 11 and 12, it is possible suppress unnecessary conduction between the low-potential terminal 11 and the sealing conductor 61.

The embodiment described above deals with an example where a second functional device 60 is formed. The second functional device 60, however, is not essential, and can be omitted.

The embodiment described above deals with an example where a dummy pattern 85 is formed. The dummy pattern 85 however is not essential and can be omitted.

The embodiment described above deals with an example where the first functional device 45 is of a multichannel type that includes a plurality of transformers 21. It is however also possible to employ a single-channel first functional device 45 that includes a single transformer 21.

### Transformer Layout

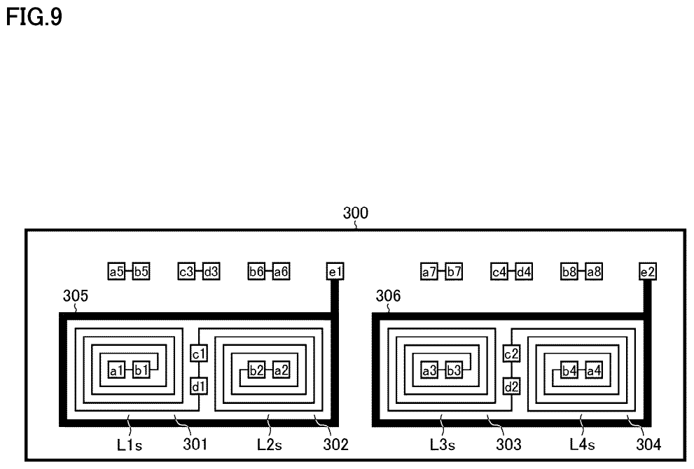

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 304, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate of the transformer chip 300, to obtain a desired withstand voltage between the primary and secondary coils. The first and second guard rings 305 and 306 are, however, not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### Detection Circuit (First Embodiment)

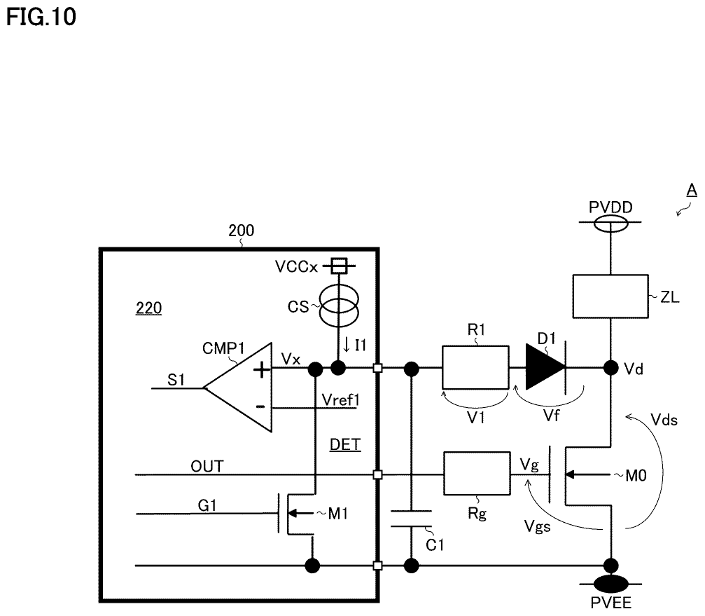

FIG. 10 is a diagram showing a first embodiment (=corresponding to a comparative example to be compared with a later-described second embodiment) of a detection circuit DET. The detection circuit DET is provided, for example, in an above-described signal transmission device 200 (particularly, driver chip 220). The signal transmission device 200 may be, for example, a semiconductor integrated circuit device, so-called isolated gate driver IC, to be mounted on an electronic device A in combination with a power transistor M0 and a load ZL that are externally provided to the signal transmission device 200. The electronic device A may be exemplified by an on-vehicle traction inverter.

The signal transmission device 200, as shown in foregoing FIG. 1, transmits an input pulse signal IN of a primary circuit system 200p as an output pulse signal OUT of a secondary circuit system 200s while keeping electrical isolation between the primary circuit system 200p and the secondary circuit system 200s. The output pulse signal OUT is equivalent to a drive signal of the power transistor M0. As shown in the figure, a gate resistor Rg may be externally provided between the output pulse signal OUT and a gate of the power transistor M0.

The power transistor M0, which is a driving object of the signal transmission device 200, may be an n-channel MOS field-effect transistor as an example. A long and according to this figure, the drain of the power transistor M0 is connected to a first end of the load ZL. A second end of the load ZL is connected to an application end of a first-power-system supply voltage PVDD. The first-power-system supply voltage PVDD may be 400 to 1200 V, as an example. The source of the power transistor M0 is connected to an application end of a second-power-system supply voltage PVEE. The second-power-system supply voltage PVEE may be 0 V as an example. The second-power-system supply voltage PVEE may be a negative voltage (<0 V).

A gate voltage Vg (and therefore an output pulse signal OUT as well) is applied to the gate of the power transistor M0. The power transistor M0 goes to on status when a gate-source voltage Vgs (=Vg-PVEE) is higher than an on-threshold voltage Vth(M0). On the other hand, when the gate-source voltage Vgs is lower than the on-threshold voltage Vth(M0), the power transistor M0 goes to off status.

The detection circuit DET detects whether or not there has arisen a short-circuited state across the load ZL, in other words, whether or not the drain of the power transistor M0 has been directly connected to the application end of the first-power-system supply voltage PVDD without being via the load ZL. From a different point of view, the detection circuit DET detects whether or not there has arisen an abnormal state in which a short-circuit overcurrent can flow through the power transistor M0 due to a short circuit of the load ZL.

In keeping with the figure, the detection circuit DET includes a comparator CMP1, a current source CS, a resistor R1, a diode D1, a transistor M1, and a capacitor C1. The transistor M1 may be an N-channel type one, for example. These component elements may be, at least partly, contained in the signal transmission device 200.

The comparator CMP1 compares a node voltage Vx to be inputted to a noninverting input end (+) and a reference voltage Vref1 to be inputted to an inverting input end (−) with each other to generate a comparison signal S1. When the node voltage Vx is higher than the reference voltage Vref 1, the comparison signal S1 goes to high level. On the other hand, when the node voltage Vx is lower than the reference voltage Vref1, the comparison signal S1 goes to low level. The reference voltage Vref1 may be 9 V as an example. The comparator CMP1 may be contained in the signal transmission device 200.

The current source CS is connected between an application end of a supply voltage VCCx and an application end of the node voltage Vx to supply a bias current 11 toward the application end of the node voltage Vx. The current source CS may be contained in the signal transmission device 200 or externally provided to the signal transmission device 200. The supply voltage VCCx may be a supply voltage VCC2 of, e.g., 15 to 18 V or a voltage higher than the node voltage Vx.

A first end of the resistor R1 is connected to the application end of the node voltage Vx. A second end of the resistor R1 is connected to an anode of the diode D1. A cathode of the diode D1 is connected to the drain of the power transistor M0. Like this, the resistor R1 and the diode D1 may be connected in series between the application end of the node voltage Vx and the drain of the power transistor M0.

In this case, the node voltage Vx obtained under a condition with no short circuit occurring to the load ZL can increase up to a voltage value (=Vd+V1+Vf) resulting from adding a voltage V1 (=11×R1) across the resistor R1 and a forward dropping voltage Vf of the diode D 1 to the drain voltage Vd of the power transistor M0. Accordingly, adjusting the resistance value of the resistor R1 allows the node voltage Vx, and therefore a threshold for switching of logic level of the comparison signal S1 as well, to be adjusted. Also, the resistor R1 restricts a forward current of the diode D1 that occurs when the drain-source voltage Vds has swung to negative. However, the resistor R1 may be omitted. The resistor R1 and the diode D1 may be externally provided to the signal transmission device 200.

A drain of the transistor M1 is connected to the application end of the node voltage Vx. A source of the transistor M1 is connected to the source of the power transistor M0 and, therefore, also to the application end of the second-power-system supply voltage PVEE. A gate of the transistor M1 is connected to an application end of a gate signal G1. The transistor M1 is set to on status while the gate signal G1 is at high level. In this state, a voltage across the capacitor C1, i.e. node voltage Vx, is dissipated. Meanwhile, the transistor M1 stays at off status while the gate signal G1 is at low level. In this state, the node voltage Vx is charged by the bias current 11. The transistor M1 may also be contained in the signal transmission device 200.

The gate signal G1 may be arranged so as to fall from high to low level along with transition of the output pulse signal OUT to high level. That is, the transistor M1 may be on/off switched complementarily with the power transistor M0. In other words, the transistor M1 may be switched from on to off status along with turn-on of the power transistor M0.

A first end of the capacitor C1 is connected to the application end of the node voltage Vx. A second end of the capacitor C1 is connected to the source of the power transistor M0, and therefore also to the application end of the second-power-system supply voltage PVEE. The capacitor C1 is provided to set later-described blanking time Tbr. The capacitor C1 may also be externally provided to the signal transmission device 200.

The detection circuit DET of this embodiment adopts, as a means of detecting a short-circuit state of the load ZL, the DESAT method functioning to monitor drain-source unsaturation of the power transistor M0. More specifically, while the power transistor M0 is at on status, the detection circuit DET detects whether or not the node voltage Vx responsive to the drain-source voltage Vds (=vd-PVEE) of the power transistor M0 is higher than the reference voltage Vref1.

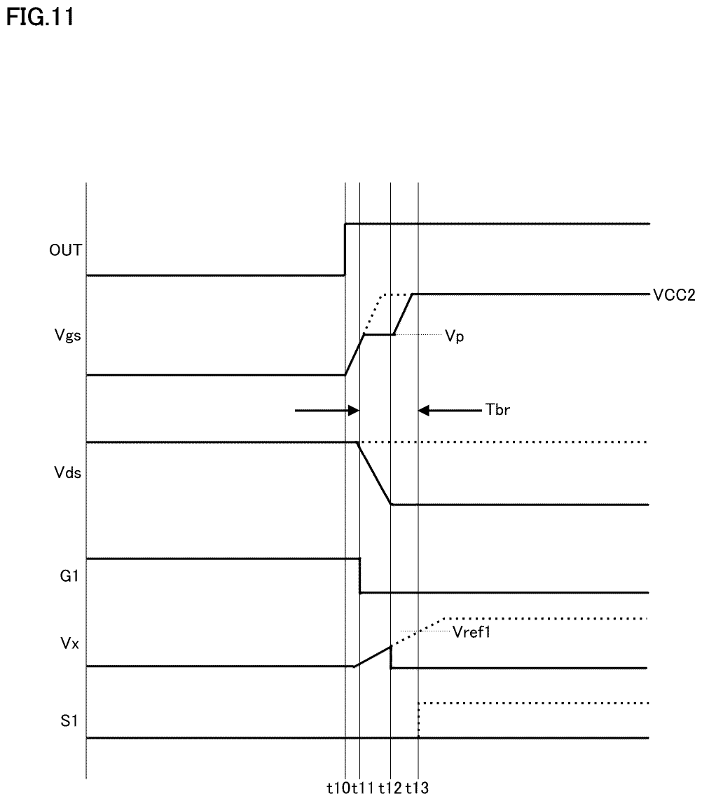

FIG. 11 is a chart showing a detection operation for a load short circuit in the first embodiment. Depicted in this figure, in descending order from the uppermost row, are the output pulse signal OUT, the gate-source voltage Vgs, the drain-source voltage Vds, the gate signal G1, the node voltage Vx, and the comparison signal S1. Solid line indicates behavior of these elements in a state with no short circuit occurring to the load ZL. In contrast, broken line indicates behavior of the elements with a short circuit occurring to the load ZL.

When the output pulse signal OUT is set to rise from low to high level at time t10, the gate-source voltage Vgs starts to rise.

With no short circuit occurring to the load ZL, at time t11 to t12, while the gate-source voltage Vgs is held at a plateau voltage Vp by mirror effect, the drain-source voltage Vds falls from high toward low level. Such an operational region can be interpreted as a so-called plateau region. The plateau voltage Vp may be 10 V, as an example. Thereafter, at time t12, the gate-source voltage Vgs turns to rise again, and moreover the drain-source voltage Vds reaches low level (˜0 V).

In addition, after the output pulse signal OUT is set to rise from low to high level, the gate signal G1, for example at time t11, is turned to fall from high to low level. As a result, the transistor M1 goes to off status, causing the node voltage Vx to start rising at a time constant t corresponding to a capacitance value of the capacitor C1.

However, with no short circuit occurring to the load ZL, the drain-source voltage Vds falls to low level before the node voltage Vx exceeds the reference voltage Vref1, i.e., at time t12 in the figure. Accordingly, the node voltage Vx falls to low level, remaining below the reference voltage Vref1. As a result, the comparison signal S1 is held at low level. It is noted that the low level of the comparison signal S1 can be interpreted as a logic level corresponding to an abnormality-undetected situation.

Meanwhile, with a short circuit occurring to the load ZL, the gate-source voltage Vgs rises up to high level (˜VCC2) almost without slowdown after the foregoing time t10. Also, the drain-source voltage Vds is held at high level (˜VCC2) without falling therefrom. Accordingly, the node voltage Vx continues rising at the foregoing time constant t, exceeding the reference voltage Vref1 at time t13. As a result, the comparison signal S1 rises to high level. It is noted that the high level of the comparison signal S1 can be interpreted as a logic level corresponding to an abnormality-detected situation (load short-circuit detected situation).

The signal transmission device 200 may appropriately be equipped with a function of compulsorily setting off the power transistor M0 when the comparison signal S1 has come to high level, i.e., the so-called load-short-circuit protection function.

As to the detection circuit DET of the DESAT method, there is provided blanking time Tbr (=t11 to t13) with an aim of avoiding misdetection of the node voltage Vx under a fall of the drain-source voltage Vds during a period of time t11 to t12, i.e., in the plateau region.

The blanking time Tbr can be set to an arbitrary length by adjusting the capacitance value of the capacitor C1 and moreover a boost gradient (time constant t) of the node voltage Vx. More specifically, the blanking time Tbr needs to be set to enough length (generally 1 us or so) to avoid misdetection of the node voltage Vx in consideration of fabrication variations of the power transistor M0, fluctuations of load circumstances, junction-temperature variations of the power transistor M0, and the like.

In another aspect, there is a tendency that short-circuit tolerance of the power transistor M0 becomes smaller along with recent years' performance enhancement of the power transistor M0. Therefore, elongated blanking time Tbr might cause the load-short-circuit protection operation responsive to the comparison signal S1 to be prevented from being prepared in time.

This being the case, in view of the discussions given hereinabove, a second embodiment is proposed below which is capable of promptly detecting short circuits of the load ZL without requiring any blanking time Tbr.

### Detection Circuit (Second Embodiment)

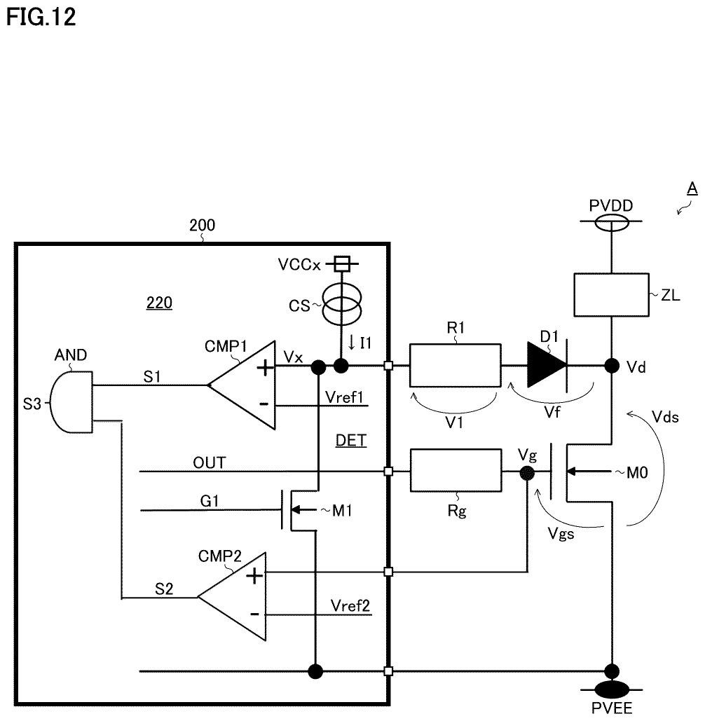

FIG. 12 is a diagram showing a second embodiment of the detection circuit DET. The detection circuit DET of this embodiment, fundamentally based on the foregoing first embodiment (FIG. 10), further includes a comparator CMP2 and an AND gate AND. Also, the foregoing capacitor C1 is removed.

The comparator CMP2 compares a gate voltage Vg of the power transistor M0 inputted to an noninverting input end (+) and a reference voltage Vref2 inputted to an inverting input end (-) with each other to generate a comparison signal S2. The comparison signal S2 goes to high level when the gate voltage Vg is higher than the reference voltage Vref2. On the other hand, the comparison signal S2 goes to low level when the gate voltage Vg is lower than the reference voltage Vref2. The reference voltage Vref2 may be 13 V as an example. That is, the reference voltage ref2 may be set to a voltage which is lower than the high level (˜VCC2) of the gate voltage Vg and which is higher than the plateau voltage Vp of the power transistor M0. The comparator CMP2 may be contained in the signal transmission device 200.

The AND gate AND, upon receiving inputs of the comparison signals S1 and S2, performs logical AND operation to output a detection signal S3. The detection signal S3 goes to low level when at least either one of the comparison signals S1 and S2 is at low level. On the other hand, the detection signal S3 goes to high level when both comparison signals S1 and S2 are at high level.

The AND gate AND is equivalent to a logic circuit which sets the detection signal S3 to high level when the node voltage Vx is higher than the reference voltage Vref1 and moreover the gate voltage Vg is higher than the reference voltage Vref2, i.e., when both comparison signals S1 and S2 are at high level. It is noted that the high level of the detection signal S3 can be interpreted as a logic level corresponding to an abnormality-detected situation (load short-circuit detected situation). The AND gate AND may also be contained in the signal transmission device 200.

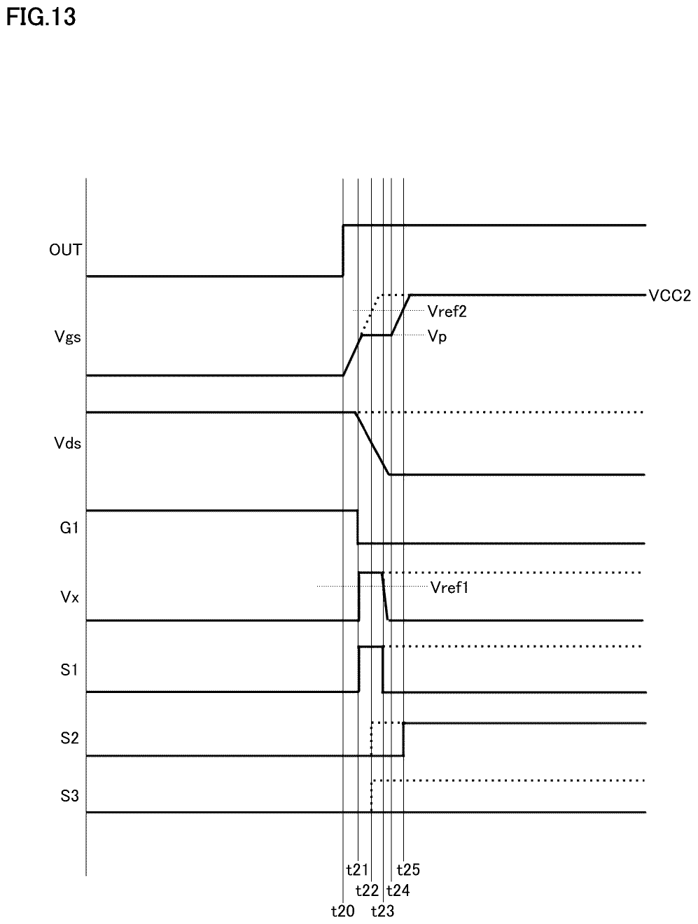

FIG. 13 is a chart showing a detection operation for a load short circuit in the second embodiment. Depicted in this figure, in descending order from the uppermost row, are an output pulse signal OUT, a gate-source voltage Vgs, a drain-source voltage Vds, a gate signal G1, a node voltage Vx, a comparison signal S1, a comparison signal S2, and a detection signal S3. Solid line indicates behavior of these elements in a state with no short circuit occurring to the load ZL. In contrast, broken line indicates behavior of the elements with a short circuit occurring to the load ZL.

When the output pulse signal OUT has been set to rise from low to high level at time t20, the gate-source voltage Vgs starts to rise.

With no short circuit occurring to the load ZL, at time t21 to t24, the drain-source voltage Vds falls from high toward low level while the gate-source voltage Vgs is held at the plateau voltage Vp by mirror effect. Such an operational region can be interpreted as a so-called plateau region. The plateau voltage Vp may be 10 V as an example. Thereafter, at time t24, the gate-source voltage Vgs turns to rise again while the drain-source voltage Vds reaches low level (˜0V). Such behavior has no noticeable difference from the behavior of the first embodiment (time t11 to t12 in FIG. 11).

In addition, after the output pulse signal OUT has been set to rise from low to high level, the gate signal G1 is made to fall from high to low level, for example, at time t21. As a result, the transistor M1 is set to off status. The detection circuit DET of this embodiment includes no capacitor C1 unlike the foregoing first embodiment (FIG. 10). Accordingly, as the transistor M1 turns off, the node voltage Vx exceeds the reference voltage Vref1 without delay. As a result, the comparison signal S1 rises to high level.

However, with no short circuit occurring to the load ZL, the gate-source voltage Vgs is held below the reference voltage Vref2 under a fall of the drain-source voltage Vds during a period of time t21 to t24, i.e., in the plateau region. Accordingly, the comparison signal S2 is held at low level, so that the detection signal S3 also remains still at low level. It is noted that the low level of the detection signal S3 can be interpreted as a logic level corresponding to an abnormality-undetected situation.

Also, as the drain-source voltage Vds falls during the period of t21 to t24, the node voltage Vx goes below the reference voltage Vref1 again before expiration of the plateau region, i.e., at time t23 in the figure. Therefore, the comparison signal S1 falls to low level.

At time t25 after the expiration of the plateau region, as the gate-source voltage Vgs exceeds the reference voltage Vref2, the comparison signal S2 rises to high level. However, at this time point, the comparison signal S1 has already fallen to low level. Therefore, the detection signal S3 remains still at low level.

On the other hand, with a short circuit occurring to the load ZL, the gate-source voltage Vgs rises up to high level (˜VCC2) almost without a slowdown after the foregoing time t20. Then, when the gate-source voltage Vgs exceeds the reference voltage Vref2 at time t22, the comparison signal S2 rises to high level.

Also, as the transistor M1 is switched to off status at time t21, the node voltage Vx exceeds the reference voltage Vref1 without delay. As a result, the comparison signal S1 rises to high level. In addition, with a short circuit occurring to the load ZL, the drain-source voltage Vds is held as it is without falling from high level (˜PVDD). Accordingly, the node voltage Vx also remains still above the reference voltage Vref1, so that the comparison signal S1 is held at high level.

In summary, with a short circuit occurring to the load ZL, the detection signal S3 rises to high level at time t22. Then, after the time t22 onward, both comparison signals S1 and S2 are held at high level, so that the detection signal S3 remains still at high level. It is noted that the high level of the detection signal S3, as previously mentioned, can be interpreted as a logic level corresponding to an abnormality-detected situation (load short-circuit detected situation).

The signal transmission device 200 may appropriately be equipped with a function of compulsorily setting off the power transistor M0 when the detection signal S3 has come to high level, i.e., the so-called load-short-circuit protection function.

It is known that, as described above, while the power transistor M0 has been turned on completely, the gate-source voltage Vgs of the power transistor M0 becomes higher than the plateau voltage Vp. By utilizing such a characteristic, the detection circuit DET of this embodiment is so configured as to detect the drain-source voltage Vds of the power transistor M0 only when the gate-source voltage Vgs of the power transistor M0 is higher than the plateau voltage Vp.

According to this embodiment, a short circuit of the load ZL can be detected without delay and without involving the foregoing blanking time Tbr. Therefore, a time duration required until the load-short-circuit protection operation is activated, for example, a time duration from when the gate signal G1 has been set to fall to low level at time t21 until when the detection signal S3 rises to high level at time t22, becomes a considerably shorter one (e.g., 500 ns or so) as compared with the foregoing first embodiment (1 μs or so). As a result, safety in short-circuited situation of the load ZL can be ensured even under a condition that the short-circuit tolerance of the power transistor M0 is relatively small.

### Detection Circuit (Third Embodiment)

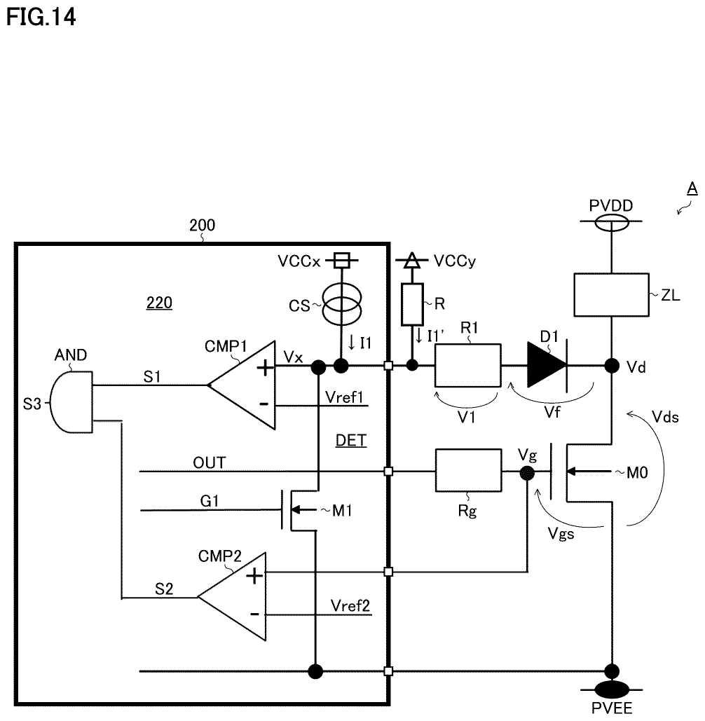

FIG. 14 is a diagram showing a third embodiment of the detection circuit DET. The detection circuit DET of this embodiment, fundamentally based on the foregoing second embodiment (FIG. 12), further includes a resistor R.

The resistor R is connected between an application end of a supply voltage VCCy and an application end of the node voltage Vx. The resistor R may be externally provided to the signal transmission device 200. With such a configuration, a bias current I1′ can be generated via the resistor R. The resistor R, as shown in this figure, may be provided in parallel to the current source CS. Otherwise, in relation to the insertion of the resistor R, the current source CS may be omitted. Also, the supply voltage VCCy may be given by the supply voltage VCC2 or by a voltage higher than the node voltage Vx. The supply voltage VCCy and the supply voltage VCCx may be identical in value to each other or different in value from each other.

### Detection Circuit (Fourth Embodiment)

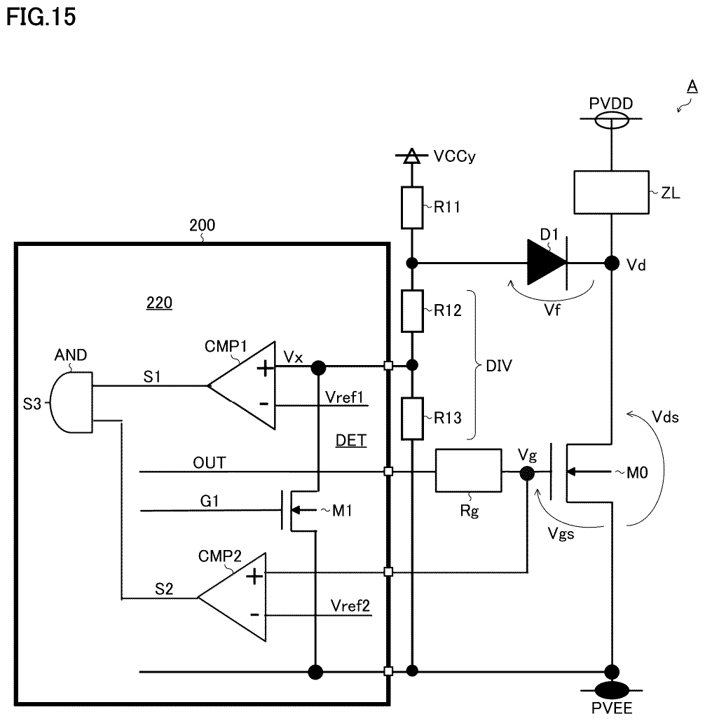

FIG. 15 is a diagram showing a fourth embodiment of the detection circuit DET. The detection circuit DET of this embodiment, fundamentally based on the foregoing second embodiment (FIG. 12), further includes resistors R11 to R13. Also, the foregoing resistor R1 and current source CS are removed.

A first end of the resistor R11 is connected to an application end of the supply voltage VCCy. A second end of the resistor R11 and a first end of the resistor R12 are both connected to an anode of the diode D1. A second end of the resistor R12 and a first end of the resistor R13 are both connected to the application end of the node voltage Vx. A second end of the resistor R13 is connected to the source of the power transistor M0 and, therefore, also to the application end of the second-power-system supply voltage PVEE. In addition, as shown in this figure, in relation to external provision of the resistors R11 to R13, the current source CS may be omitted. Otherwise, like the foregoing second embodiment (FIG. 12), the current source CS may be provided.

The resistors R12 and R13 connected as described above function as a voltage divider circuit DIV that divides the drain voltage Vd (more precisely, Vd+Vf) to generate a node voltage Vx (=(Vd+Vf)×R13/(R12+R13)). In addition, the supply voltage VCCy may be given by the supply voltage VCC2 or by a voltage higher than the drain voltage Vd (more precisely, Vd+Vf).

According to the detection circuit DET of this embodiment, it becomes possible to arbitrarily adjust the drain voltage Vd resulting when the comparison signal S1 is switched to high level, i.e., the DESAT detection voltage (=Vref1×(R12+R13)/R13−Vf).

### Discussions on Misdetection of Load Short Circuit

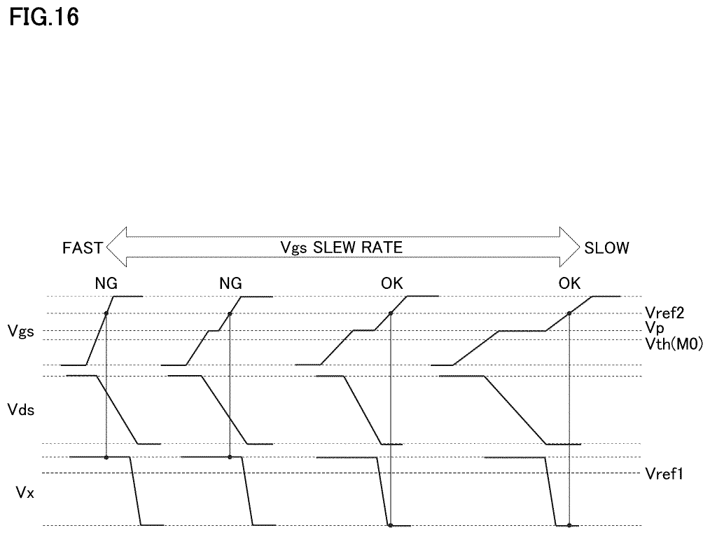

FIG. 16 is a chart showing a relationship between a slew rate of gate-source voltage Vgs and individual-component voltages in the second embodiment. Depicted in this figure, in descending order from the uppermost row, are the gate-source voltage Vgs and drain-source voltage Vds of the power transistor M0, and the node voltage Vx. In addition, the gate-source voltage Vgs may be interpreted as the gate voltage Vg. Also, the drain-source voltage Vds may be interpreted as the drain voltage Vd.

Further, it is assumed that the slew rate of the gate-source voltage Vgs becomes increasingly faster leftward and increasingly slower rightward, as viewed in the drawing sheet, more and more. For example, the larger the gate current of the power transistor M0 or the smaller the gate capacitance of the power transistor M0, the faster the slew rate of the gate-source voltage Vgs. Conversely, the smaller the gate current of the power transistor M0 or the larger the gate capacitance of the power transistor M0, the slower the slew rate of the gate-source voltage Vgs.

As shown in this figure, a faster slew rate of the gate-source voltage Vgs might cause the gate-source voltage Vgs to exceed the reference voltage Vref2 in transition sections of the drain-source voltage Vds. Under this condition, a node voltage Vx higher than the reference voltage Vref1 could cause a misdetection that a short circuit has occurred to the load ZL.

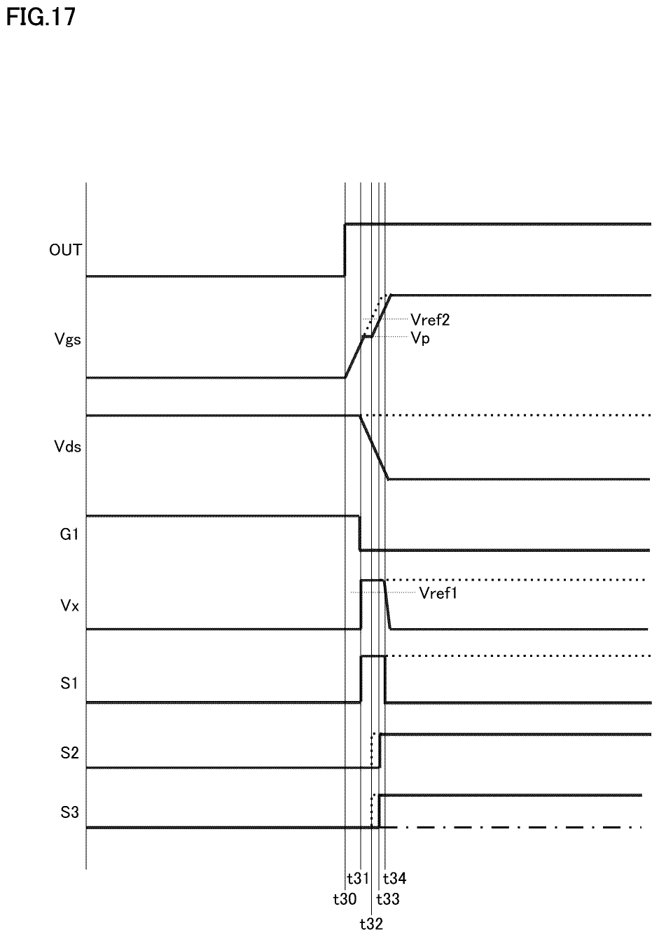

FIG. 17 is a chart showing a misdetection of a load short circuit in the second embodiment. Depicted in this figure, in descending order from the uppermost row as in foregoing FIG. 13, are the output pulse signal OUT, the gate-source voltage Vgs, the drain-source voltage Vds, the gate signal G1, the node voltage Vx, the comparison signal S1, the comparison signal S2, and the detection signal S3. Solid line indicates behavior of these elements in a state with no short circuit occurring to the load ZL. In contrast, broken line indicates behavior of the elements with a short circuit occurring to the load ZL. Further, this figure shows behavior in a case of a fast slew rate of the gate-source voltage Vgs.

When the output pulse signal OUT is set to rise from low to high level at time t30, the gate-source voltage Vgs starts to rise.

With no short circuit occurring to the load ZL, at time t31, while the gate-source voltage Vgs is held at a plateau voltage Vp by mirror effect, the drain-source voltage Vds starts to fall from high toward low level.

In addition, the gate signal G1 is set to fall from high to low level, for example, at time t31. As a result, the transistor M1 goes to off status. In this case, the node voltage Vx exceeds the reference voltage Vref1 without delay. As a result, the comparison signal S1 rises to high level. The behavior described up to this point is basically the same as in the foregoing second embodiment (FIG. 13).

However, a faster slew rate of the gate-source voltage Vgs might cause the gate-source voltage Vgs to exceed the reference voltage Vref2 in transition sections of the drain-source voltage Vds. Under the condition of this figure, the gate-source voltage Vgs turns to rise again at time t32, and the gate-source voltage Vgs exceeds the reference voltage Vref2 at time t33. Therefore, the comparison signal S2 rises to high level, so that the comparison signal S1 is through outputted as the detection signal S3.

In addition, at this time point, the drain-source voltage Vds has not yet fallen to low level (˜0V). Therefore, as shown in this figure, there can arise a situation in which the node voltage Vx exceeds the reference voltage Vref1 at a timing when the comparison signal S2 rises to high level, i.e., a situation in which the comparison signal S1 is held at high level. Under this condition, even with no short circuit occurring to the load ZL, the detection signal S3 is switched to high level, i.e., switched to a logic level corresponding to an abnormality-detected situation (load short-circuit detected situation).

Such a misdetection of load short circuits could occur, similarly, even to the detection circuits DET of the third embodiment (FIG. 14) and the fourth embodiment (FIG. 15).

In view of the above discussions, there will be proposed hereinafter novel embodiments which are enabled, by proper setting of the blanking time Tbr, to suppress misdetections of load short circuits even when higher slew rates of the gate-source voltage Vgs are involved.

### Blanking Time (First Setting Example)

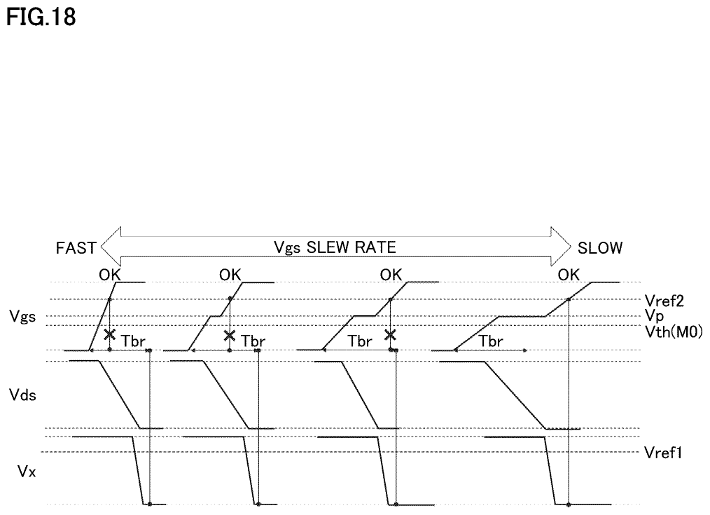

FIG. 18 is a chart showing a first setting example of the blanking time Tbr. Depicted in this figure, in descending order from the uppermost row as in foregoing FIG. 16, are the gate-source voltage Vgs and drain-source voltage Vds of the power transistor M0, and the node voltage Vx. Further, it is assumed that the slew rate of the gate-source voltage Vgs becomes increasingly faster leftward and increasingly slower rightward, as viewed in the drawing sheet, more and more.

In the first setting example, as shown in the figure, a blanking time Tbr of a specified length is set with its starting point given by a rise-start timing of the gate-source voltage Vgs. The detection circuit DET may be so configured as to execute detection of a load short circuit corresponding to a comparison result between the node voltage Vx and the reference voltage Vref1 only when the blanking time Tbr has elapsed and moreover the gate-source voltage Vgs exceeds the reference voltage Vref2. In addition, the rise-start timing of the gate-source voltage Vgs may also be interpreted as a rise-instruction timing of the output pulse signal OUT, and therefore, also as a turn-on instruction timing of the power transistor M0.

For example, in a case where a fast slew rate of the gate-source voltage Vgs is involved, i.e. according to the figure, where the gate-source voltage Vgs exceeds the reference voltage Vref2 before elapsing of the blanking time Tbr, the detection of a load short circuit corresponding to a comparison result between the node voltage Vx and the reference voltage Vref1 may be executed at a time point when the blanking time Tbr has elapsed.

On the other hand, for example, in a case where a slower slew rate of the gate-source voltage Vgs is involved, i.e. according to the figure, where the gate-source voltage Vgs exceeds the reference voltage Vref2 after elapsing of the blanking time Tbr, the detection of a load short circuit corresponding to a comparison result between the node voltage Vx and the reference voltage Vref1 may be executed at a time point when the gate-source voltage Vgs has exceeded the reference voltage Vref2.

According to this configuration, it becomes implementable to suppress misdetections of load short circuits even under a condition of a high slew rate of the gate-source voltage Vgs. Also, in the first embodiment (FIG. 10), there is a need for estimating the blanking time Tbr as an excessive one. In contrast, according to the first setting example of this figure, the need for setting the blanking time Tbr to an excessive one is eliminated by combination with the gate voltage detection. Therefore, it also becomes implementable to detect a short circuit of the load ZL without delay at a level comparable with the second embodiment (FIG. 12).

### Detection Circuit (Fifth Embodiment)

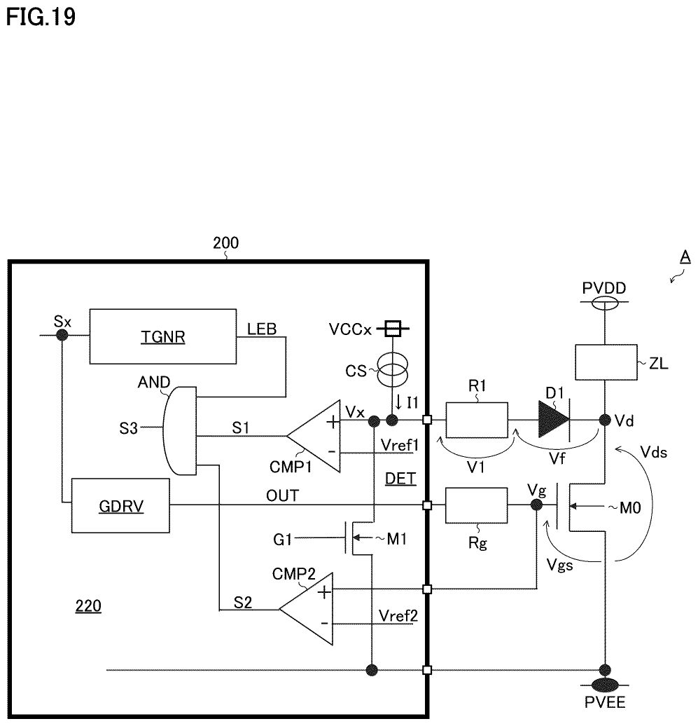

FIG. 19 is a diagram showing a fifth embodiment of the detection circuit DET. The detection circuit DET of this embodiment, fundamentally based on the foregoing second embodiment (FIG. 12), further includes a blanking-time generation circuit TGNR. Also in this figure, a gate drive circuit GDRV is expressly shown as a circuit component integrated in the driver chip 220.

In addition, the detection circuit DET of this embodiment can be interpreted as a circuit configuration aimed at implementing the first setting example (FIG. 18) of the blanking time Tbr explained previously.

The gate drive circuit GDRV, upon receiving an input of a gate control signal Sx, generates an output pulse signal OUT. For example, the gate drive circuit GDRV may set the output pulse signal OUT to high level when the gate control signal Sx is at high level. Also, for example, the gate drive circuit GDRV may set the output pulse signal OUT to low level when the gate control signal Sx is at low level. The gate drive circuit GDRV can be interpreted as the foregoing driver 224. The gate control signal Sx can be interpreted as a logic signal to be outputted from the foregoing pulse reception circuit 223.

The blanking-time generation circuit TGNR, upon receiving an input of the gate control signal Sx, generates a timing signal LEB. For example, the blanking-time generation circuit TGNR sets the timing signal LEB to rise from low to high level at a time point when the blanking time Tbr has elapsed since a rise of the gate control signal Sx to high level. That is, the timing signal LEB may also be interpreted as a delay signal for the gate control signal Sx.

In addition, the blanking time Tbr may be a variable responsive to an external setting. A means for external setting may be SPI [Serial Peripheral Interface] communication or an externally provided resistor or the like.

The AND gate AND, upon receiving not only inputs of the comparison signals S1 and S2 but also an input of the timing signal LEB, executes a logical AND operation to output a detection signal S3. The detection signal S3 goes to low level when at least one of the comparison signals S1 and S2 and the timing signal LEB is at low level. On the other hand, the detection signal S3 goes to high level when all of the comparison signals S1 and S2 and the timing signal LEB are at high level.

The AND gate AND is equivalent to a logic circuit which sets the detection signal S3 to high level when the node voltage Vx is higher than the reference voltage Vref1, the gate voltage Vg is higher than the reference voltage Vref2, and the blanking time Tbr has elapsed, i.e., when all of the comparison signals S1 and S2 and the timing signal LEB are at high level. In addition, the high level of the detection signal S3 can be interpreted as a logic level corresponding to an abnormality-detected situation (load short-circuit detected situation). The AND gate AND may be contained in the signal transmission device 200.

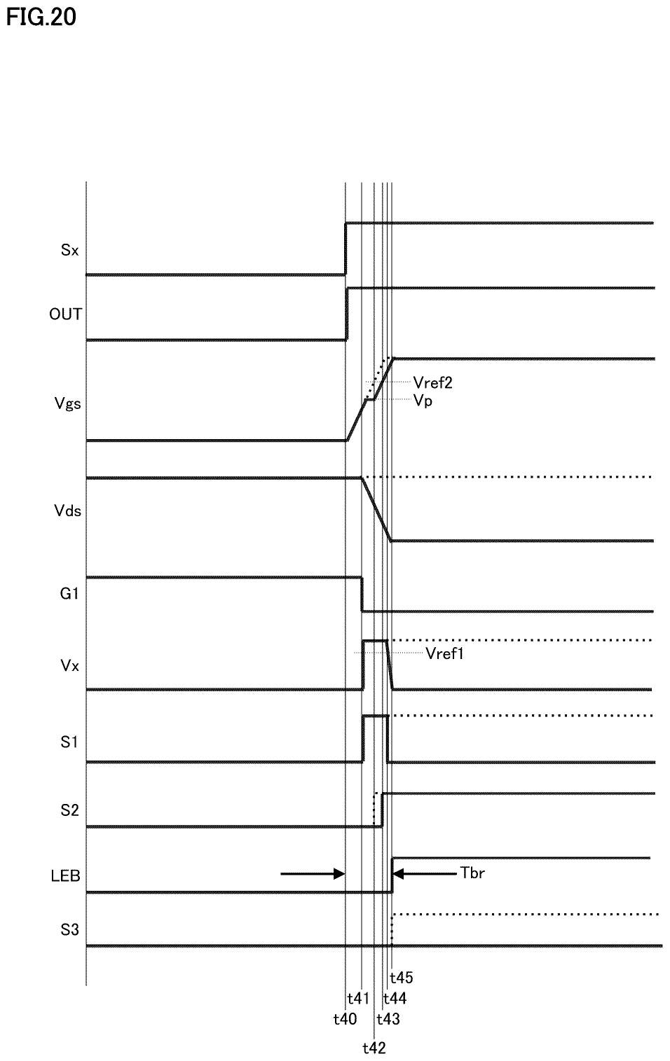

FIG. 20 is a chart showing a detection operation for a load short circuit in the fifth embodiment. Depicted in this figure, in descending order from the uppermost row, are the gate control signal Sx, the output pulse signal OUT, the gate-source voltage Vgs, the drain-source voltage Vds, the gate signal G1, the node voltage Vx, the comparison signal S1, the comparison signal S2, the timing signal LEB, and the detection signal S3. Solid line indicates behavior of these elements in a state with no short circuit occurring to the load ZL. In contrast, broken line indicates behavior of the elements with a short circuit occurring to the load ZL. Further, this figure shows behavior in a case of a fast slew rate of the gate-source voltage Vgs.

When the gate control signal Sx is set to rise from low to high level at time t40, the output pulse signal OUT is set to rise from low to high level. As a result, the gate-source voltage Vgs starts to rise. Also, when the gate control signal Sx is set to rise to high level, counting of the blanking time Tbr gets started.

With no short circuit occurring to the load ZL, at time t41, while the gate-source voltage Vgs is held at the plateau voltage Vp by mirror effect, the drain-source voltage Vds starts to fall from high toward low level.

The gate signal G1 is set to fall from high to low level, for example, at time t41. As a result, the transistor M1 goes to off status. In this case, the node voltage Vx exceeds the reference voltage Vref1 without delay. Therefore, the comparison signal S1 rises to high level. The behavior described up to this point is basically the same as in the foregoing second embodiment (FIG. 13).

However, a faster slew rate of the gate-source voltage Vgs might cause the gate-source voltage Vgs to exceed the reference voltage Vref2 in transition sections of the drain-source voltage Vds. Under the condition of this figure, the gate-source voltage Vgs turns to rise again at time t42, and the gate-source voltage Vgs exceeds the reference voltage Vref2 at time t43. Therefore, the comparison signal S2 rises to high level.

In addition, at this time point, the drain-source voltage Vds has not yet fallen to low level (˜0V). Therefore, as shown in this figure, there can arise a situation in which the node voltage Vx exceeds the reference voltage Vref1 at a timing when the comparison signal S2 rises to high level, i.e., a situation in which the comparison signal S1 is held at high level.

In consequence, assuming that no blanking time Tbr has been introduced, even under a short-circuit nonoccurrence of the load ZL, the detection signal S3 would be switched to high level, i.e., a logic level corresponding to an abnormality-detected situation (load short-circuit detected situation).

On the other hand, according to the detection circuit DET of this embodiment, the timing signal LEB is held at low level until the blanking time Tbr elapses. Therefore, even though both comparison signals S1 and S2 are at high level, the detection signal S3 is held at low level, i.e., a logic level corresponding to an abnormality-undetected situation.

At time t44, the node voltage Vx goes below the reference voltage Vref1 once again along with a fall of the drain-source voltage Vds. Thus, the comparison signal S1 falls to low level.

Thereafter, as the blanking time Tbr expires, the timing signal LEB rises to high level at time t45. However, at this time point, the comparison signal S1 has already fallen to low level. Thus, the detection signal S3 stays still at low level.

According to this configuration, it becomes implementable to suppress misdetections of load short circuits even when higher slew rates of the gate-source voltage Vgs are involved.

### Blanking Time (Second Setting Example)

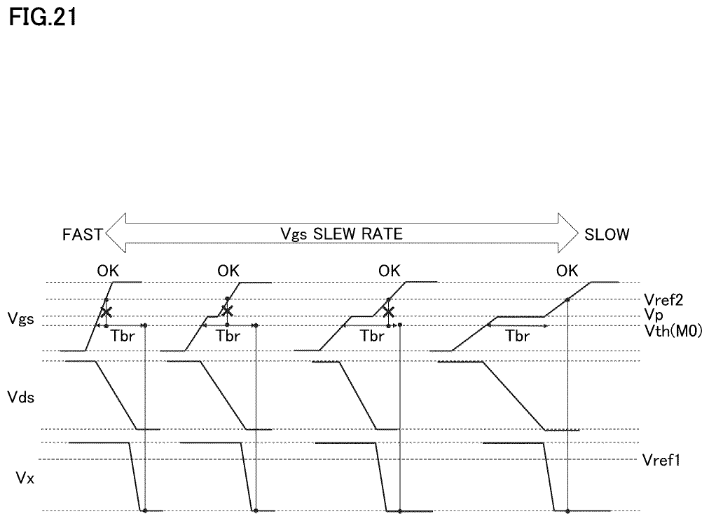

FIG. 21 is a chart showing a second setting example of the blanking time Tbr. Depicted in this figure, in descending order from the uppermost row as in foregoing FIG. 16 and FIG. 18, are the gate-source voltage Vgs and drain-source voltage Vds of the power transistor M0, and the node voltage Vx. Also, it is assumed that the slew rate of the gate-source voltage Vgs becomes increasingly faster leftward and increasingly slower rightward, as viewed in the drawing sheet, more and more.

As shown in this figure, in the second setting example, there is set a blanking time Tbr of a specified length with a starting point given by a timing when the gate-source voltage Vgs exceeds an on-threshold voltage Vth(M0) of the power transistor M0, i.e., a timing when the power transistor M0 is turned on.

According to this configuration, as in the foregoing first setting example (FIG. 18), it becomes implementable to suppress misdetections of load short circuits even when higher slew rates of the gate-source voltage Vgs are involved. Further, since there is no need for setting the blanking time Tbr to any excessive one, it becomes also implementable to detect a short circuit of the load ZL without delay.

### Detection Circuit (Sixth Embodiment)

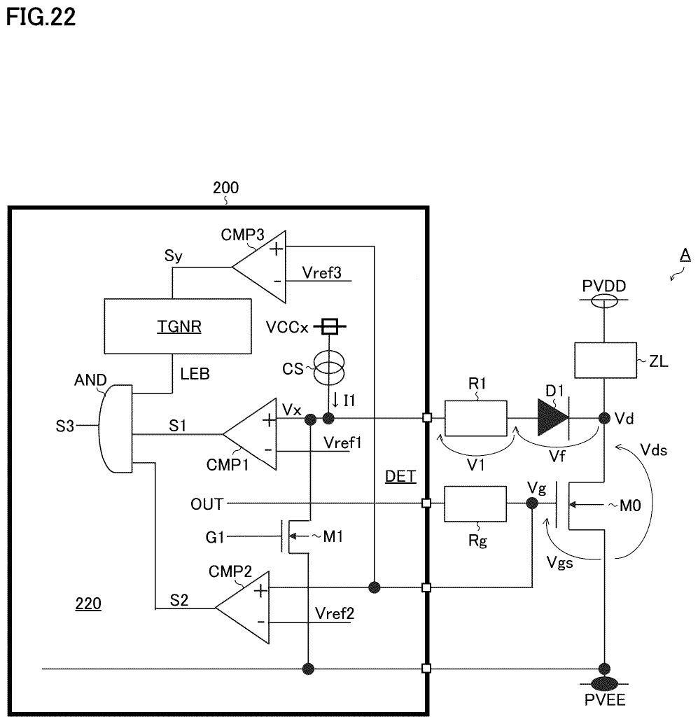

FIG. 22 is a diagram showing a sixth embodiment of the detection circuit DET. The detection circuit DET of this embodiment, fundamentally based on the foregoing second embodiment (FIG. 12), further includes a comparator CMP3, and a blanking-time generation circuit TGNR.

In addition, the detection circuit DET of this embodiment can be interpreted as a circuit configuration aimed at implementing the second setting example (FIG. 21) of the blanking time Tbr explained previously.

The comparator CMP3 compares a gate voltage Vg inputted to a noninverting input end (+) and a reference voltage Vref3 inputted to an inverting input end (−) with each other to generate a comparison signal Sy. The comparison signal Sy goes to high level when the gate voltage Vg is higher than the reference voltage Vref3. On the other hand, the comparison signal Sy goes to low level when the gate voltage Vg is lower than the reference voltage Vref3.

The reference voltage Vref3 can be interpreted as a threshold voltage intended to detect whether or not the gate-source voltage Vgs of the power transistor M0 exceeds the on-threshold voltage Vth(M0). Therefore, the reference voltage Vref3 can be set to a voltage value lower than the foregoing reference voltage Vref2. For example, the reference voltage Vref3 may be set to a voltage higher than the low level (˜GND2) of the gate voltage Vg and lower than the plateau voltage Vp of the power transistor M0. Also for example, the reference voltage Vref3 may be set to either a threshold voltage (M0) or a value of a threshold voltage (M0) ±1V. Like this, the reference voltage Vref3 may be set appropriately as required. In addition, the comparator CMP3 may be contained in the signal transmission device 200.

The blanking-time generation circuit TGNR, upon receiving an input of the comparison signal Sy, generates a timing signal LEB. For example, the blanking-time generation circuit TGNR sets the timing signal LEB to rise from low to high level at a time point when the blanking time Tbr has elapsed since a rise to high level of the comparison signal Sy. That is, the timing signal LEB may also be interpreted as a delay signal of the comparison signal Sy.

The AND gate AND, upon receiving not only inputs of the comparison signals S1 and S2 but also an input of the timing signal LEB, executes a logical AND operation to output the detection signal S3. The detection signal S3 goes to low level when at least one of the comparison signals S1 and S2 and the timing signal LEB is at low level. On the other hand, the detection signal S3 goes to high level when all of the comparison signals S1 and S2 and the timing signal LEB are at high level.

The AND gate AND is equivalent to a logic circuit which sets the detection signal S3 to high level when the node voltage Vx is higher than the reference voltage Vref1, the gate voltage Vg is higher than the reference voltage Vref2, and the blanking time Tbr has elapsed, i.e., when all of the comparison signals S1 and S2 and the timing signal LEB are at high level. In addition, the high level of the detection signal S3 can be interpreted as a logic level corresponding to an abnormality-detected situation (load short-circuit detected situation). The AND gate AND may be contained in the signal transmission device 200. Like this, configuration and operation of the AND gate AND are the same as in the foregoing fifth embodiment (FIG. 19).

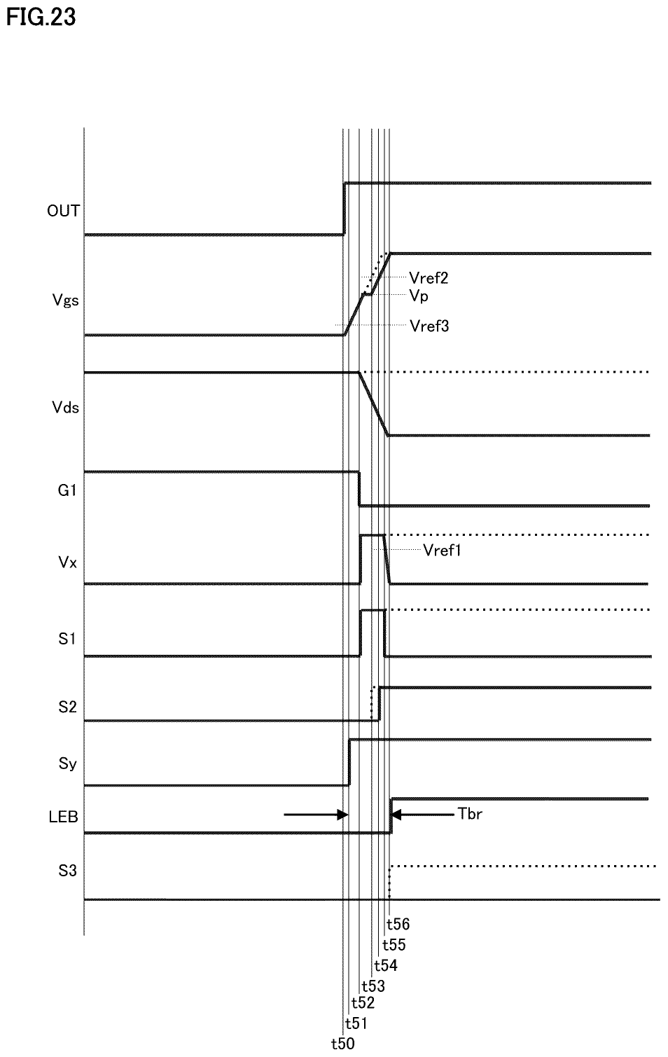

FIG. 23 is a chart showing a detection operation for a load short circuit in the sixth embodiment. Depicted in this figure, in descending order from the uppermost row, are the output pulse signal OUT, the gate-source voltage Vgs, the drain-source voltage Vds, the gate signal G1, the node voltage Vx, the comparison signal S1, the comparison signal S2, the comparison signal Sy, the timing signal LEB, and the detection signal S3. Solid line indicates behavior of these elements in a state with no short circuit occurring to the load ZL. In contrast, broken line indicates behavior of the elements with a short circuit occurring to the load ZL. Further, this figure shows behavior in a case of a fast slew rate of the gate-source voltage Vgs.

When the output pulse signal OUT is set to rise from low to high level at time t50, the gate-source voltage Vgs starts to rise.

When the gate-source voltage Vgs exceeds the reference voltage Vref3 at time t51, the comparison signal Sy rises to high level. When the comparison signal Sy has risen to high level, counting of the blanking time Tbr gets started.

With no short circuit occurring to the load ZL, at time t52, while the gate-source voltage Vgs is held at the plateau voltage Vp by mirror effect, the drain-source voltage Vds starts to fall from high toward low level.

The gate signal G1 is set to fall from high to low level, for example, at time t52. As a result, the transistor M1 goes to off status. In this case, the node voltage Vx exceeds the reference voltage Vref1 without delay. Therefore, the comparison signal S1 rises to high level.

However, a faster slew rate of the gate-source voltage Vgs might cause the gate-source voltage Vgs to exceed the reference voltage Vref2 in transition sections of the drain-source voltage Vds. Under the condition of this figure, the gate-source voltage Vgs turns to rise again at time t53, and the gate-source voltage Vgs exceeds the reference voltage Vref2 at time t54. Therefore, the comparison signal S2 rises to high level.

In addition, at this time point, the drain-source voltage Vds has not yet fallen to low level (˜0V). Therefore, as shown in this figure, there can arise a situation in which the node voltage Vx exceeds the reference voltage Vref1 at a timing when the comparison signal S2 rises to high level, i.e., a situation in which the comparison signal S1 is held at high level.

In consequence, assuming that no blanking time Tbr has been introduced, even under a short-circuit nonoccurrence of the load ZL, the detection signal S3 would be switched to high level, i.e., a logic level corresponding to an abnormality-detected situation (load short-circuit detected situation).

On the other hand, according to the detection circuit DET of this embodiment, the timing signal LEB is held at low level until the blanking time Tbr elapses. Therefore, even though both comparison signals S1 and S2 are at high level, the detection signal S3 is held at low level, i.e., a logic level corresponding to an abnormality-undetected situation.

At time t55, the node voltage Vx goes below the reference voltage Vref1 once again along with a fall of the drain-source voltage Vds. Thus, the comparison signal S1 falls to low level.

Thereafter, as the blanking time Tbr expires, the timing signal LEB rises to high level at time t56. However, at this time point, the comparison signal S1 has already fallen to low level. Thus, the detection signal S3 stays still at low level.

According to this configuration, it becomes implementable to suppress misdetections of load short circuits even when higher slew rates of the gate-source voltage Vgs are involved.

### Blanking Time (Third Example)

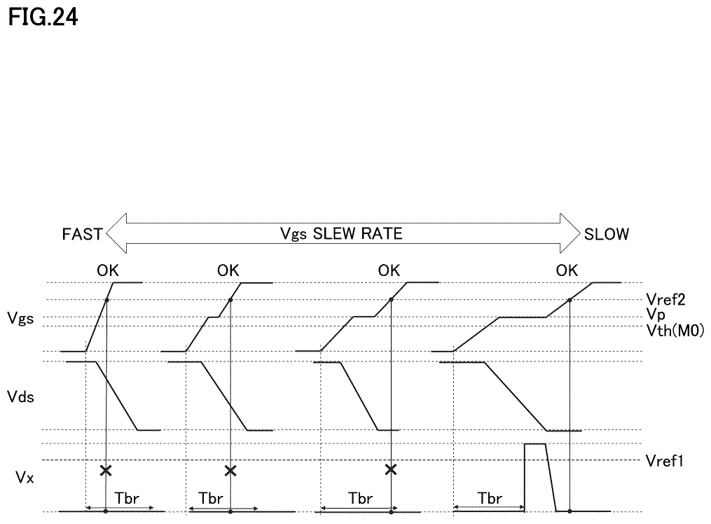

FIG. 24 is a chart showing a third setting example of the blanking time Tbr. Depicted in this figure, in descending order from the uppermost row as in foregoing FIGS. 16, FIG. 18 and FIG. 21, are the gate-source voltage Vgs and drain-source voltage Vds of the power transistor M0, and the node voltage Vx. Also, it is assumed that the slew rate of the gate-source voltage Vgs becomes increasingly faster leftward and increasingly slower rightward, as viewed in the drawing sheet, more and more.

As shown in this figure, in the third setting example as in the foregoing first setting example (FIG. 18), a blanking time Tbr of a specified length is set with its starting point given by a rise-start timing of the gate-source voltage Vgs, i.e., a turn-on instruction timing for the power transistor M0. However, in the third setting example, unlike the foregoing first setting example, it is not the case that a comparison result between the node voltage Vx and the reference voltage Vref1 is masked before elapsing of the blanking time Tbr, but it is the case that the node voltage Vx is compulsorily pulled down.

For example, in a case where a fast slew rate of the gate-source voltage Vgs is involved, i.e. according to the figure, where the gate-source voltage Vgs exceeds the reference voltage Vref2 before elapsing of the blanking time Tbr, the node voltage Vx is fixed at a low level lower than the reference voltage Vref1 until the blanking time Tbr elapses.

On the other hand, for example, in a case where a slower slew rate of the gate-source voltage Vgs is involved, i.e. according to the figure, where the gate-source voltage Vgs exceeds the reference voltage Vref2 after elapsing of the blanking time Tbr, the pull-down released node voltage Vx and the reference voltage Vref1 are compared with each other at a time point when the gate-source voltage Vgs has exceeded the reference voltage Vref2.

According to this configuration, as in the foregoing first setting example (FIG. 18) and second setting example (FIG. 21), it becomes implementable to suppress misdetections of load short circuits even under a condition of a high slew rate of the gate-source voltage Vgs. Also, since there is no need for setting the blanking time Tbr to an excessive one, it becomes implementable to detect a short circuit of the load ZL without delay.

### Detection Circuit (Seventh Embodiment)

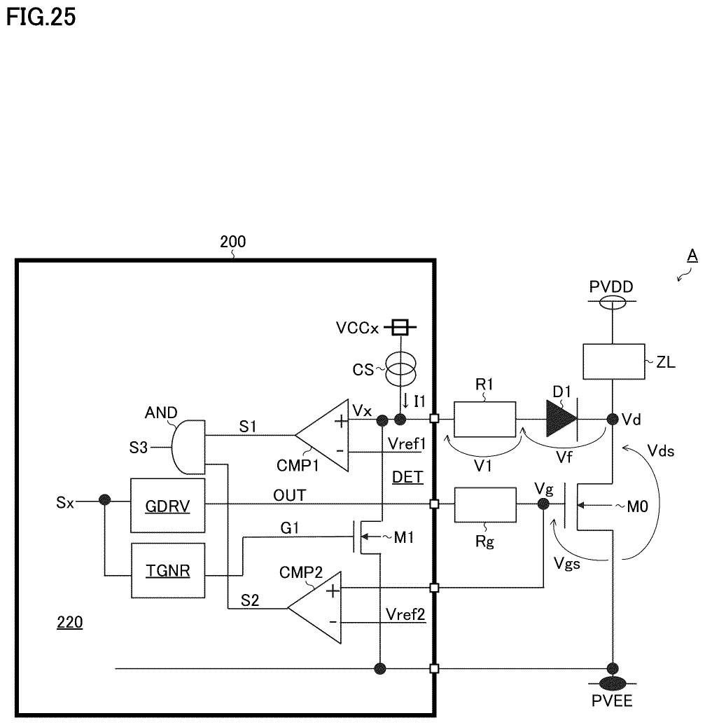

FIG. 25 is a diagram showing a seventh embodiment of the detection circuit DET. The detection circuit DET of this embodiment, fundamentally based on the foregoing fifth embodiment (FIG. 19), is so configured that an output end of the blanking-time generation circuit TGNR is connected not to the AND gate AND but to the gate of the transistor M1.

In addition, the detection circuit DET of this embodiment can be interpreted as a circuit configuration aimed at implementing the third setting example (FIG. 24) of the blanking time Tbr explained previously.

The blanking-time generation circuit TGNR, upon receiving an input of the gate control signal Sx, generates a gate signal G1. For example, the blanking-time generation circuit TGNR sets the gate signal G1 to fall from high to low level at a time point when the blanking time Tbr has elapsed since a rise to high level of the gate control signal Sx. That is, the gate signal G1 can be interpreted as an inverted delay signal of the gate control signal Sx.

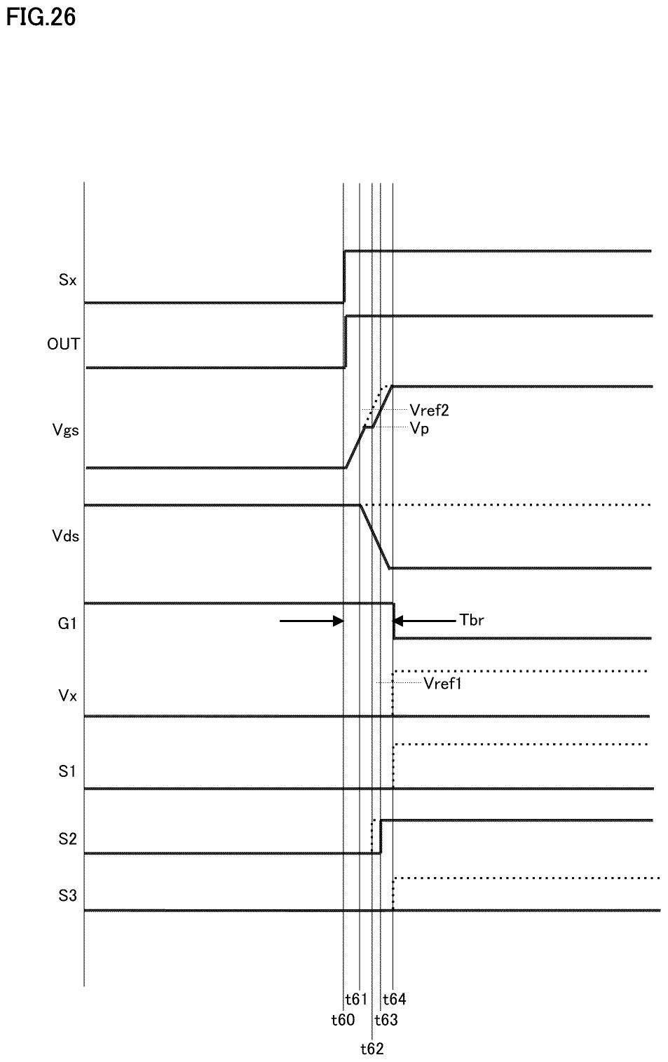

FIG. 26 is a chart showing a detection operation for a load short circuit in the seventh embodiment. Depicted in this figure, in descending order from the uppermost row, are the gate control signal Sx, the output pulse signal OUT, the gate-source voltage Vgs, the drain-source voltage Vds, the gate signal G1, the node voltage Vx, the comparison signal S1, the comparison signal S2, and the detection signal S3. Solid line indicates behavior of these elements in a state with no short circuit occurring to the load ZL. In contrast, broken line indicates behavior of the elements with a short circuit occurring to the load ZL. Further, this figure shows behavior in a case of a fast slew rate of the gate-source voltage Vgs.

When the gate control signal Sx is set to rise from low to high level at time t60, the output pulse signal OUT is set to rise from low to high level. As a result, the gate-source voltage Vgs starts to rise. Also, when the gate control signal Sx is set to rise to high level, counting of the blanking time Tbr gets started.

With no short circuit occurring to the load ZL, at time t61, while the gate-source voltage Vgs is held at the plateau voltage Vp by mirror effect, the drain-source voltage Vds starts to fall from high toward low level.

The gate signal G1 is held at high level until the blanking time Tbr elapses. As a result, the transistor M1 goes to on status, causing the node voltage Vx to be pulled down to a low level lower than the reference voltage Vref1. Thus, the comparison signal S1 is held at low level.

In addition, a faster slew rate of the gate-source voltage Vgs might cause the gate-source voltage Vgs to exceed the reference voltage Vref2 in transition sections of the drain-source voltage Vds. Under the condition of this figure, the gate-source voltage Vgs turns to rise again at time t62, and the gate-source voltage Vgs exceeds the reference voltage Vref2 at time t63. Therefore, the comparison signal S2 rises to high level.

In addition, at this time point, the drain-source voltage Vds has not yet fallen to low level (˜0V). However, in the case of the detection circuit DET of this embodiment, the comparison signal S1 is held at low level until the blanking time Tbr elapses. Therefore, the detection signal S3 as well is held at low level, i.e., at a logic level corresponding to an abnormality-undetected situation.

Thereafter, as the blanking time Tbr expires, the gate signal G1 falls to low level at time t64. Therefore, the transistor M1 is set to off status, causing the node voltage Vx to be released from being pulled down. At this time point, along with the fall of the drain-source voltage Vds, the node voltage Vx is below the reference voltage Vref1. Thus, since the comparison signal S1 is held at low level, the detection signal S3 stays still at low level.

According to this configuration, it becomes implementable to suppress misdetections of load short circuits even when higher slew rates of the gate-source voltage Vgs are involved.

### Detection Circuit (Eighth Embodiment)

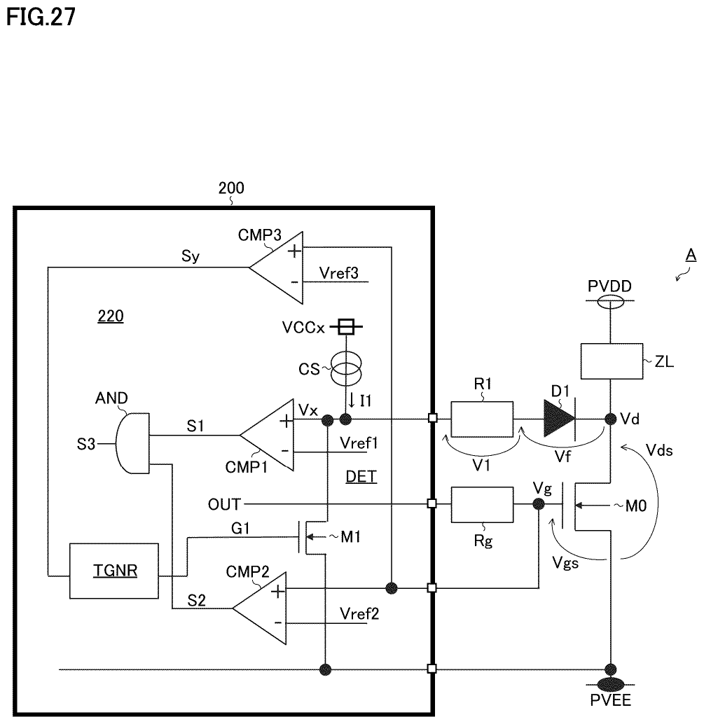

FIG. 27 is a diagram showing an eighth embodiment of the detection circuit. The detection circuit DET of this embodiment, fundamentally based on the foregoing sixth embodiment (FIG. 22), is so configured that an output end of the blanking-time generation circuit TGNR is connected not to the AND gate AND but to the gate of the transistor M1.

The blanking-time generation circuit TGNR, upon receiving an input of the comparison signal Sy, generates a gate signal G1. For example, at a a time point when the blanking time Tbr has elapsed since a rise to high level of the comparison signal Sy, the blanking-time generation circuit TGNR sets the gate signal G1 to fall from high to low level. That is, the gate signal G1 may be interpreted as an inverted delay signal of the comparison signal Sy.

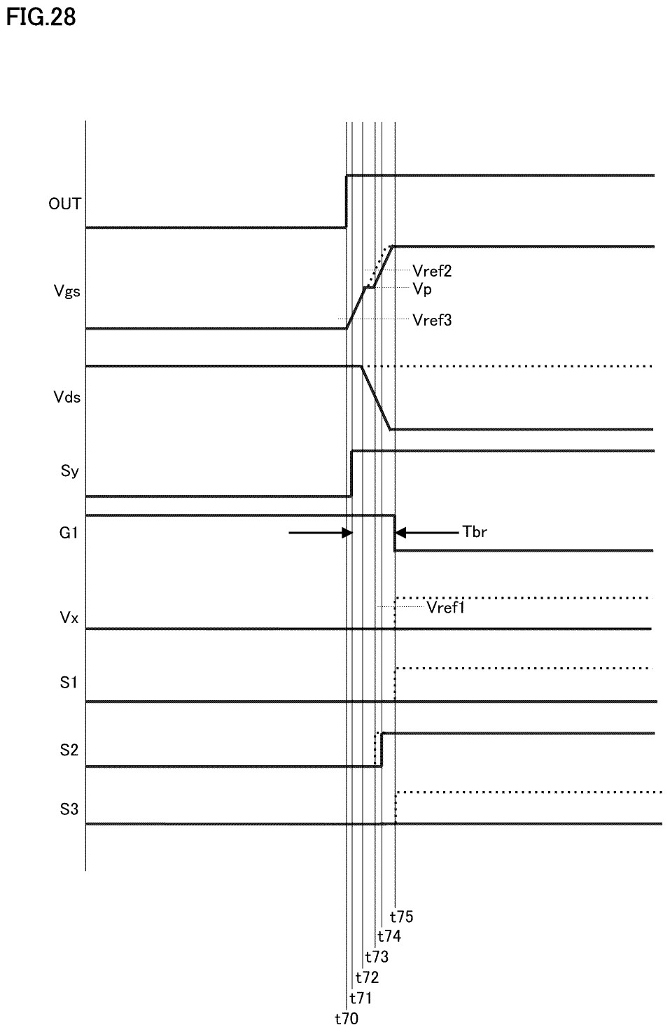

FIG. 28 is a chart showing a detection operation for a load short circuit in the eighth embodiment. Depicted in this figure, in descending order from the uppermost row, are the output pulse signal OUT, the gate-source voltage Vgs, the drain-source voltage Vds, the comparison signal Sy, the gate signal G1, the node voltage Vx, the comparison signal S1, the comparison signal S2, and the detection signal S3. Solid line indicates behavior of these elements in a state with no short circuit occurring to the load ZL. In contrast, broken line indicates behavior of the elements with a short circuit occurring to the load ZL. Further, this figure shows behavior in a case of a fast slew rate of the gate-source voltage Vgs.

When the output pulse signal OUT is set to rise from low to high level at time t70, the gate-source voltage Vgs starts to rise.

When the gate-source voltage Vgs exceeds the reference voltage Vref3 at time t71, the comparison signal Sy rises to high level. When the comparison signal Sy has risen to high level, counting of the blanking time Tbr gets started.

With no short circuit occurring to the load ZL, at time t72, while the gate-source voltage Vgs is held at the plateau voltage Vp by mirror effect, the drain-source voltage Vds starts to fall from high toward low level.

The gate signal G1 is held at high level until the blanking time Tbr elapses. As a result, the transistor M1 goes to on status, causing the node voltage Vx to be pulled down to a low level lower than the reference voltage Vref1. Thus, the comparison signal S1 is held at low level.

In addition, a faster slew rate of the gate-source voltage Vgs might cause the gate-source voltage Vgs to exceed the reference voltage Vref2 in transition sections of the drain-source voltage Vds. Under the condition of this figure, the gate-source voltage Vgs turns to rise again at time t73, and the gate-source voltage Vgs exceeds the reference voltage Vref2 at time t74. Therefore, the comparison signal S2 rises to high level.

In addition, at this time point, the drain-source voltage Vds has not yet fallen to low level (˜0V). However, in the case of the detection circuit DET of this embodiment, the comparison signal S1 is held at low level until the blanking time Tbr elapses. Therefore, the detection signal S3 as well is held at low level, i.e., at a logic level corresponding to an abnormality-undetected situation.

Thereafter, as the blanking time Tbr expires, the gate signal G1 falls to low level at time t75. Therefore, the transistor M1 is set to off status, causing the node voltage Vx to be released from being pulled down. At this time point, along with the fall of the drain-source voltage Vds, the node voltage Vx is below the reference voltage Vref1. Thus, since the comparison signal S1 is held at low level, the detection signal S3 stays still at low level.

According to this configuration, it becomes implementable to suppress misdetections of load short circuits even when higher slew rates of the gate-source voltage Vgs are involved.

### Combinations Among Embodiments

In the foregoing fifth to eighth embodiments (FIGS. 19, FIG. 22, FIG. 25, and FIG. 27), the blanking-time generation circuit TGNR is introduced on a basis of the second embodiment (FIG. 12) in each case. However, the configurations of those embodiments are given each only as an example, and the blanking-time generation circuit TGNR may also be introduced on a basis of, for example, the third embodiment (FIG. 14) or the fourth embodiment (FIG. 15).

### Modifications

In addition, the power transistor M0 in the above-described embodiments may be an IGBT as an example. In such a case, drain and source of the power transistor M0 are substituted by collector and emitter, respectively, of the power transistor M0. Also, drain-source voltage Vds and gate-source voltage Vgs are substituted by collector-emitter voltage Vce and gate-emitter voltage Vge, respectively.

### Application to Vehicles

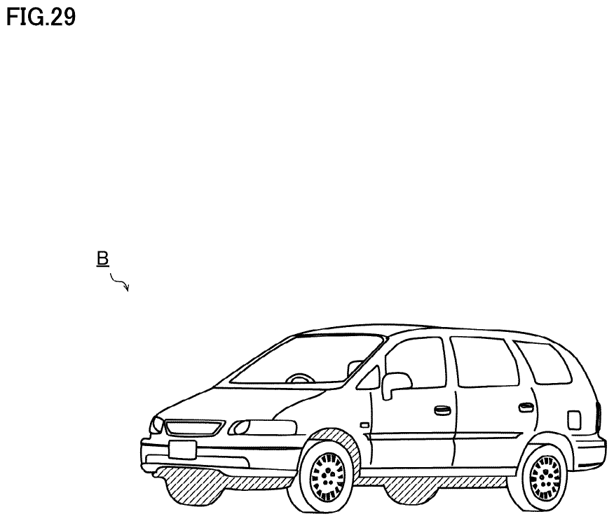

FIG. 29 is a view showing an appearance of a vehicle. The vehicle B of this configuration example is equipped with various electronic devices that operate on power supply derived from a battery.

The vehicle B may be exemplified not only by engine vehicles but also by electric vehicles (xEV's such as BEV [battery electric vehicle], HEV [hybrid electric vehicle], PHEV/PHV [plug-in hybrid electric vehicle/plug-in hybrid vehicle], or FCEV/FCV (fuel cell electric vehicle/fuel cell vehicle]).

In addition, the signal transmission device 200 explained hereinabove may be incorporated into any one of electronic devices mounted on the vehicle B.

### Appendices

Any one of the detection circuits according to the present disclosure is enabled to detect a short circuit of a load without delay. Appendices on the disclosure are given below.

### Appendix 1

A detection circuit (DET) comprising:
a first comparator (CMP1) configured to compare a node voltage (Vx), which is responsive to a drain-source voltage (Vds) or a collector-emitter voltage (Vce) of a power transistor (M0), and a first reference voltage (Vref1) with each other to generate a first comparison signal (S1);
a second comparator (CMP2) configured to compare a gate voltage (Vg) of the power transistor (M0) and a second reference voltage (Vref2) with each other to generate a second comparison signal (S2); and
a logic circuit (AND) configured to output a detection signal (S3) upon reception of inputs of the first comparison signal (S1) and the second comparison signal (S2).

### Appendix 2

The detection circuit (DET) as described in appendix 1, wherein the second reference voltage (Vref2) is higher than a plateau voltage (Vp) of the power transistor (M0).

### Appendix 3

The detection circuit (DET) as described in appendix 2, wherein when the node voltage (Vx) is higher than the first reference voltage (Vref1) and the gate voltage (Vg) is higher than the second reference voltage (Vref2), the logic circuit sets the detection signal (S3) to a logic level corresponding to an abnormality-detected situation.

### Appendix 4

The detection circuit (DET) as described in any one of appendices 1 to 3, further comprising a diode (D1) connected between an application end of the node voltage (Vx) and the drain or the collector of the power transistor (M0).

### Appendix 5

The detection circuit (DET) as described in any one of appendices 1 to 4, further comprising a resistor (R1) connected between the application end of the node voltage (Vx) and the drain or the collector of the power transistor (M0).

### Appendix 6

The detection circuit (DET) as described in any one of appendices 1 to 5, further comprising at least one of a current source (CS) and a resistor (R), whichever it is configured to supply a bias current (I1, I1′) toward the application end of the node voltage (Vx).

### Appendix 7

The detection circuit (DET) as described in any one of appendices 1 to 6, further comprising a transistor (M1) which is connected between the application end of the node voltage (Vx) and the source or the emitter of the power transistor (M0) and which is configured so as to be turned on/off complementarily with the power transistor (M0).

### Appendix 8

The detection circuit (DET) as described in any one of appendices 1 to 7, further comprising a voltage divider circuit (DIV) configured to divide the drain-source voltage (Vds) of the power transistor (M0) or a voltage responsive to the drain-source voltage to generate the node voltage (Vx).

### Appendix 9

The detection circuit (DET) as described in any one of appendices 1 to 8, further comprising a blanking-time generation circuit (TGNR) configured to generate a blanking time (Tbr) of a specified length, wherein until the blanking time (Tbr) elapses, the detection signal (S3) is held at a logic level corresponding to an abnormality-undetected situation.

### Appendix 10

The detection circuit (DET) as described in appendix 9, wherein the blanking time (Tbr) is set with a starting point given by a timing of turn-on instruction for the power transistor (M0).

### Appendix 11

The detection circuit (DET) as described in appendix 9, wherein the blanking time (Tbr) is set with a starting point given by a timing for turn-on of the power transistor (M0).

### Appendix 12

The detection circuit (DET) as described in appendix 11, further comprising a third comparator (CMP3) configured to compare the gate voltage (Vg) of the power transistor (M0) and a third reference voltage (Vref3) lower than the second reference voltage (Vref2) with each other to generate a third comparison signal (Sy), wherein the blanking-time generation circuit (TGNR) generates the blanking time (Tbr) upon reception of an input of the third comparison signal (Sy).

### Appendix 13

The detection circuit (DET) as described in any one of appendices 9 to 12, wherein until the blanking time (Tbr) elapses, the logic circuit (AND) holds the detection signal (S3) fixed at the logic level corresponding to an abnormality-undetected situation without depending on respective logic levels of the first comparison signal (S1) and the second comparison signal (S2).

### Appendix 14

The detection circuit (DET) as described in any one of appendices 9 to 12, wherein until the blanking time (Tbr) elapses, the node voltage (Vx) is fixed at a voltage lower than the first reference voltage (Vref1).

### Appendix 15

A signal transmission device (200) which is configured to, while keeping electrical isolation between a primary circuit system (200p) and a secondary circuit system (200s), transmit a drive signal (OUT) for the power transistor (M0) from the primary circuit system (200p) to the secondary circuit system (200s), wherein the detection circuit (DET) as described in any one of appendices 1 to 14 is provided in the secondary circuit system (200s).

### Appendix 16

An electronic device (A) comprising:
the signal transmission device (200) as described in appendix 15; and
the power transistor (M0) externally provided to the signal transmission device (200).

### Appendix 17

A vehicle (B) comprising the electronic device (A) as described in appendix 16.

### Others

It should be noted that various technical features disclosed herein, without being limited to the above-described embodiment, may be modified in various ways unless those modifications depart from the gist of the technical creation of the disclosure. That is, the above embodiment should be construed as not being restrictive but being illustrative at all points. Also, the technical scope of the disclosure should be defined by the appended claims, and should be construed as including all changes and modifications equivalent in sense and range to the appended claims.

What is claimed is:

1. A detection circuit comprising:
a first comparator configured to compare a node voltage, which is responsive to a drain-source voltage or a collector-emitter voltage of a power transistor, and a first reference voltage with each other to generate a first comparison signal;
a second comparator configured to compare a gate voltage of the power transistor and a second reference voltage with each other to generate a second comparison signal; and
a logic circuit configured to output a detection signal upon reception of inputs of the first comparison signal and the second comparison signal.

2. The detection circuit as claimed in claim 1, wherein
the second reference voltage is higher than a plateau voltage of the power transistor.

3. The detection circuit as claimed in claim 2, wherein
when the node voltage is higher than the first reference voltage and the gate voltage is higher than the second reference voltage, the logic circuit sets the detection signal to a logic level corresponding to an abnormality-detected situation.

4. The detection circuit as claimed in claim 1, further comprising:
a diode connected between an application end of the node voltage and the drain or the collector of the power transistor.

5. The detection circuit as claimed in claim 1, further comprising:
a resistor connected between an application end of the node voltage and the drain or the collector of the power transistor.

6. The detection circuit as claimed in claim 1, further comprising:
at least one of a current source and a resistor, whichever it is configured to supply a bias current toward an application end of the node voltage.

7. The detection circuit as claimed in claim 1, further comprising:
a transistor which is connected between an application end of the node voltage and the source or the emitter of the power transistor and which is configured so as to be turned on/off complementarily with the power transistor.

8. The detection circuit as claimed in claim 1, further comprising:
a voltage divider circuit configured to divide the drain-source voltage of the power transistor or a voltage responsive to the drain-source voltage to generate the node voltage.

9. The detection circuit as claimed in claim 1, further comprising:
a blanking-time generation circuit configured to generate a blanking time of a specified length, wherein
until the blanking time elapses, the detection signal is held at a logic level corresponding to an abnormality-undetected situation.

10. The detection circuit as claimed in claim 9, wherein
the blanking time is set with a starting point given by a timing of turn-on instruction for the power transistor.

11. The detection circuit as claimed in claim 9, wherein
the blanking time is set with a starting point given by a timing for turn-on of the power transistor.

12. The detection circuit as claimed in claim 11, further comprising:
a third comparator configured to compare the gate voltage of the power transistor and a third reference voltage lower than the second reference voltage with each other to generate a third comparison signal, wherein
the blanking-time generation circuit generates the blanking time upon reception of an input of the third comparison signal.

13. The detection circuit as claimed in claim 9, wherein
until the blanking time elapses, the logic circuit holds the detection signal fixed at the logic level corresponding to an abnormality-undetected situation without depending on respective logic levels of the first comparison signal and the second comparison signal.

14. The detection circuit as claimed in claim 9, wherein
until the blanking time elapses, the node voltage is fixed at a voltage lower than the first reference voltage.

15. A signal transmission device which is configured to, while keeping electrical isolation between a primary circuit system and a secondary circuit system, transmit a drive signal for the power transistor from the primary circuit system to the secondary circuit system, wherein
the detection circuit as claimed in claim 1 is provided in the secondary circuit system.

16. An electronic device comprising:
the signal transmission device as claimed in claim 15; and
the power transistor externally provided to the signal transmission device.

17. A vehicle comprising:
the electronic device as claimed in claim 16.
